(19) United States
(12) Patent Application Publication
(10) Pub. No.: US 2026/0310095 A1
(43) Pub. Date: Oct. 8, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Chun-Hao LIN, Tainan City (TW); Yu-Jen WANG, Kaohsiung City (TW); Meng-Ying LI, Tainan City (TW); Chun-Hao CHOU, Tainan City (TW)

(21) Appl. No.: 19/169,642

(22) Filed: Apr. 3, 2025

(51) Int. Cl. G03F 7/00; H10W 20/00

(52) U.S. Cl. CPC G03F 7/70475; G03F 7/70733; H10W 20/089; G03F 7/70033

(57) ABSTRACT

A multiple-reticle exposure technique is used to manufacture different lateral regions of a semiconductor device (e.g., a monolithic superchip). The multiple-reticle exposure technique may be used for frontside processing and for backside processing of a semiconductor device. For example, different sets of reticles may be used to pattern different lateral regions on the frontside of the semiconductor device, and different sets of reticles may be used to pattern different lateral regions on the backside of the semiconductor device. This further expands the capability of implementing diverse sets of functional areas across the semiconductor device to the backside as well as the frontside for the semiconductor device. Moreover, the use of the multiple-reticle exposure technique on the backside of the semiconductor device is compatible with direct bonding of the semiconductor device to another semiconductor device to form three-dimensional integrated circuit (3DIC) devices.

### BACKGROUND

An extreme ultraviolet (EUV) radiation source includes a collector, which includes a curved mirror that is configured to collect EUV radiation and to focus the EUV radiation toward an intermediate focus near an intermediate focus cap (IF cap) of the EUV radiation source. The EUV radiation is produced from a laser produced plasma (LPP) that is generated by exposing droplets of tin (Sn) to a carbon dioxide (CO₂) laser. The Sn droplets are generated by a droplet generator (DG) head, which provides the Sn droplets into a vacuum chamber to an irradiation site where the Sn droplets are irradiated by a focused laser beam.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an embodiment of a lithography system described herein.

FIGS. 2A and 2B are diagrams of an example implementation of a semiconductor device described herein.

FIGS. 3A-3W are diagrams of an example implementation of forming a semiconductor device described herein.

FIGS. 4A and 4B are diagrams of an example stacked semiconductor device described herein.

FIGS. 5A-5P are diagrams of an example implementation of forming a stacked semiconductor device described herein.

FIGS. 6A and 6B are diagrams of an example implementation of forming a stacked semiconductor device described herein.

FIG. 7 is a diagram of an example stacked semiconductor device described herein.

FIG. 8 is a diagram of an example stacked semiconductor device described herein.

FIG. 9 is a diagram of an example stacked semiconductor device described herein.

FIG. 10 is a diagram of an example stacked semiconductor device described herein.

FIG. 11 is a diagram of an example stacked semiconductor device described herein.

FIG. 12 is a flowchart of an example process associated with forming a semiconductor device described herein.

FIG. 13 is a flowchart of an example process associated with forming a semiconductor device described herein.

FIG. 14 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A lithography system may include a radiation source and an exposure tool. The radiation source (e.g., an extreme ultraviolet (EUV) radiation source or another type of radiation source) may be configured to generate radiation such as EUV radiation and/or another type of electromagnetic radiation (e.g., light). An exposure tool (e.g., an EUV scanner or another type of exposure tool) may be configured to focus the radiation onto a reflective reticle (or a photomask) such that a pattern is transferred from the reticle onto a semiconductor substrate using the radiation. The radiation may reflect off of the reticle based on a pattern of the reticle. The radiation may be reflected onto the semiconductor substrate such that the pattern of the reticle is transferred to the semiconductor substrate.

Various industries rely on advanced semiconductor devices for high speed, low power, and/or specialized operations. High performance compute (HPC) devices may process large amounts of data at high speed to perform complex calculations. HPC devices may include computer chips capable of performing multiple functions to perform parallel processing of data. Internet of Things (IoT) devices may include computer chips that include a diverse set of features (including processing, memory, wireless communication, and storage) all the while needing to operate efficiently and sometimes on battery power.

Communication devices (e.g., radio frequency (RF) devices, datacenter communication devices) may include computer chips that perform high speed and high bandwidth communication.

Each specialized computer chip may be integrated with multiple devices and contact structures that would otherwise be found on multiple non-specialized chips. As a result, the size of such specialized computer chips (e.g., “superchips”) may need to be larger than the non-specialized chips in order to include the devices and/or contact structures that may be required to perform a diverse set of functions. However, the size of a computer chip (e.g., a semiconductor die manufactured on a wafer) may be limited by the size of a reticle used to pattern the layers of the computer chip. This may prevent specialized computer chips from having the requisite device density to execute a diverse set of functions. As a result, multiple specialized computer chips may need to be interconnected in order to achieve such function sets, which may increase manufacturing complexity.

In some implementations described herein, a multiple-reticle exposure technique is used to manufacture monolithic superchips that have a greater amount of device area than if single-reticle exposures were used to manufacture the monolithic superchips. As described herein, different lateral regions of a semiconductor device (e.g., a monolithic superchip) may be patterned by different sets of lithography reticles. For example, a first set of reticles may be used to pattern a first lateral region of the semiconductor device, and a second set of reticles may be used to pattern a second lateral region of the semiconductor device. This enables the lateral regions of the semiconductor device to be manufactured to have particular functional areas (e.g., memory, logic, analog, communication) that are integrated onto a single monolithic superchip, as opposed to being distributed across multiple discrete computer chips that are each manufactured using a single-reticle exposure technique.

As further described herein, the multiple-reticle exposure technique may be used for frontside processing and for backside processing of a semiconductor device. For example, different sets of reticles may be used to pattern different lateral regions on the frontside of the semiconductor device, and different sets of reticles may be used to pattern different lateral regions on the backside of the semiconductor device. This further expands the capability of implementing diverse sets of functional areas across the semiconductor device to the backside as well as the frontside for the semiconductor device. Moreover, the use of the multiple-reticle exposure technique on the backside of the semiconductor device is compatible with direct bonding of the semiconductor device to another semiconductor device to form three-dimensional integrated circuit (3DIC) devices.

In this way, the multiple-reticle exposure technique described herein may be used for frontside processing and for backside processing of a semiconductor device. For example, different sets of reticles may be used to pattern different lateral regions on the frontside of the semiconductor device, and different sets of reticles may be used to pattern different lateral regions on the backside of the semiconductor device. This further expands the capability of implementing diverse sets of functional areas across the semiconductor device to the backside as well as the frontside for the semiconductor device. Moreover, the use of the multiple-reticle exposure technique on the backside of the semiconductor device is compatible with direct bonding of the semiconductor device to another semiconductor device to form 3DIC devices.

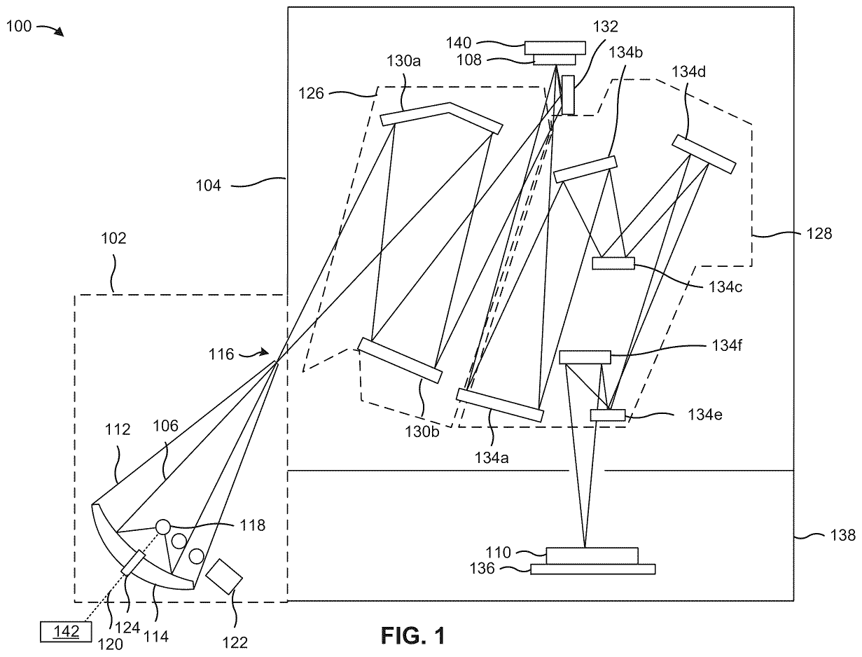

FIG. 1 is a diagram of an embodiment of a lithography system 100 described herein. The lithography system 100 includes an EUV lithography system or another type of lithography system that is configured to transfer a pattern to a semiconductor substrate using mirror-based optics. The lithography system 100 may be configured for use in a semiconductor processing environment such as a semiconductor foundry or a semiconductor fabrication facility.

As shown in FIG. 1, the lithography system 100 includes the radiation source 102 and an exposure tool 104. The radiation source 102 (e.g., an EUV radiation source or another type of radiation source) is configured to generate radiation 106 such as EUV radiation and/or another type of electromagnetic radiation (e.g., light). The exposure tool 104 (e.g., an EUV scanner or another type of exposure tool) is configured to focus the radiation 106 onto a reflective reticle 108 (or a photomask) such that a pattern is transferred from the reticle 108 onto a semiconductor wafer 110 using the radiation 106.

The radiation source 102 includes a vessel 112 and a collector 114 in the vessel 112. The collector 114 includes a curved mirror that is configured to collect the radiation 106 generated by the radiation source 102 and to focus the radiation 106 toward an intermediate focus 116. The radiation 106 is produced from a plasma that is generated from droplets 118 (e.g., tin (Sn) droplets or another type of droplets) being exposed to a laser beam 120. The droplets 118 are provided across the front of the collector 114 by a droplet generator (DG) head 122. The DG head 122 is pressurized to provide a fine and controlled output of the droplets 118.

A laser source, such as a pulse carbon dioxide (CO₂) laser, generates the laser beam 120. The laser beam 120 is provided (e.g., by a beam delivery system to a focus lens) such that the laser beam 120 is focused through a window 124 of the collector 114. The laser beam 120 is focused onto the droplets 118, which generates the plasma. The plasma produces a plasma emission, some of which is the radiation 106. The laser beam 120 is pulsed at a timing that is synchronized with the flow of the droplets 118 from the DG head 122.

The exposure tool 104 includes an illuminator 126 and a projection optics box (POB) 128. The illuminator 126 includes a plurality of reflective mirrors that are configured to focus and/or direct the radiation 106 onto the reticle 108 so as to illuminate the pattern on the reticle 108. The plurality of mirrors includes, for example, a mirror 130a and a mirror 130b. The mirror 130a includes a field facet mirror (FFM) or another type of mirror that includes a plurality of field facets. The mirror 130b includes a pupil facet mirror (PFM) or another type of mirror that also includes a plurality of pupil facets. The facets of the mirrors 130a and 130b are arranged to focus, polarize, and/or otherwise tune the radiation 106 from the radiation source 102 to increase the uniformity of the radiation 106 and/or to increase particular types of radiation components (e.g., transverse electric (TE) polarized radiation, transverse magnetic (TM) polarized radiation). Another mirror 132 (e.g., a relay mirror) is included to direct radiation 106 from the illuminator 126 onto the reticle 108.

The projection optics box 128 includes a plurality of mirrors that are configured to project the radiation 106 onto the semiconductor wafer 110 after the radiation 106 is modified based on the pattern of the reticle 108. The plurality of reflective mirrors includes, for example, mirrors 134a-134f. In some implementations, the mirrors 134a-134f are configured to focus or reduce the radiation 106 into an exposure field, which may include one or more die areas on the semiconductor wafer 110.

The exposure tool 104 includes a wafer stage 136 (e.g., a substrate stage) configured to support the semiconductor wafer 110. Moreover, the wafer stage 136 is configured to move (or step) the semiconductor wafer 110 through a plurality of exposure fields as the radiation 106 transfers the pattern from the reticle 108 onto the semiconductor wafer 110.

The wafer stage 136 is included in a bottom module 138 of the exposure tool 104. The bottom module 138 includes a removable subsystem of the exposure tool 104. The bottom module 138 may slide out of the exposure tool 104 and/or otherwise may be removed from the exposure tool 104 to enable cleaning and inspection of the wafer stage 136 and/or the components of the wafer stage 136. The bottom module 138 isolates the wafer stage 136 from other areas in the exposure tool 104 to reduce and/or minimize contamination of the semiconductor wafer 110. Moreover, the bottom module 138 may provide physical isolation for the wafer stage 136 by reducing the transfer of vibrations (e.g., vibrations in the semiconductor processing environment in which the lithography system 100 is located, vibrations in the lithography system 100 during operation of the lithography system 100) to the wafer stage 136 and, therefore, the semiconductor wafer 110. This reduces movement and/or disturbance of the semiconductor wafer 110, which reduces the likelihood that the vibrations may cause a pattern misalignment.

The exposure tool 104 also includes a reticle stage 140 that is configured to support and/or secure the reticle 108. Moreover, the reticle stage 140 is configured to move or slide the reticle through the radiation 106 such that the reticle 108 is scanned by the radiation 106. In this way, a pattern that is larger than the field or beam of the radiation 106 may be transferred to the semiconductor wafer 110.

The lithography system 100 includes a laser source 142. The laser source 142 is configured to generate the laser beam 120. The laser source 142 may include a CO₂-based laser source or another type of laser source. Due to the wavelength of the laser beams generated by a CO₂-based laser source in an infrared (IR) region, the laser beams may be highly absorbed by tin, which enables the CO₂-based laser source to achieve high power and energy for pumping tin-based plasma. In some implementations, the laser beam 120 includes a plurality of types of laser beams that the laser source 142 generates using a multi-pulse technique (or a multi-stage pumping technique), in which the laser source 142 generates a pre-pulse laser beam and main-pulse laser beam to achieve greater heating efficiency of tin (Sn)-based plasma to increase conversion efficiency.

In an example exposure operation (e.g., an EUV exposure operation), the DG head 122 provides the stream of the droplets 118 across the front of the collector 114. The laser beam 120 contacts the droplets 118, which causes a plasma to be generated. The laser source 142 generates and provides a pre-pulse laser beam toward a target material droplet in the stream of the droplets 118, and the pre-pulse laser beam is absorbed by the target material droplet. This transforms the target material droplet into a disc shape or a mist. Subsequently, the laser source 142 provides a main-pulse laser beam with large intensity and energy toward the disc-shaped target material or target material mist. Here, the atoms of the target material are neutralized, and ions are generated through thermal flux and shock wave. The main-pulse laser beam pumps ions to a higher charge state, which causes the ions to radiate the radiation 106 (e.g., EUV light).

The radiation 106 is collected by the collector 114 and directed out of the vessel 112 and into the exposure tool 104 toward the mirror 130a of the illuminator 126. The mirror 130a reflects the radiation 106 onto the mirror 130b, which reflects the radiation 106 onto the mirror 132 toward the reticle 108. The radiation 106 is modified by the pattern in the reticle 108. In other words, the radiation 106 reflects off of the reticle 108 based on the pattern of the reticle 108. The reflective reticle 108 directs the radiation 106 toward the mirror 134a in the projection optics box 128, which reflects the radiation 106 onto the mirror 134b. The radiation 106 continues to be reflected and reduced in the projection optics box 128 by the mirrors 134c-134f. The mirror 134f reflects the radiation 106 onto the semiconductor wafer 110 such that the pattern of the reticle 108 is transferred to the semiconductor wafer 110. The above-described exposure operation is an example, and the lithography system 100 may operate according to other EUV techniques and radiation paths that include a greater quantity of mirrors, a lesser quantity of mirrors, and/or a different configuration of mirrors.

As indicated above, FIG. 1 is provided as an example. Other examples may differ from what is described with regard to FIG. 1.

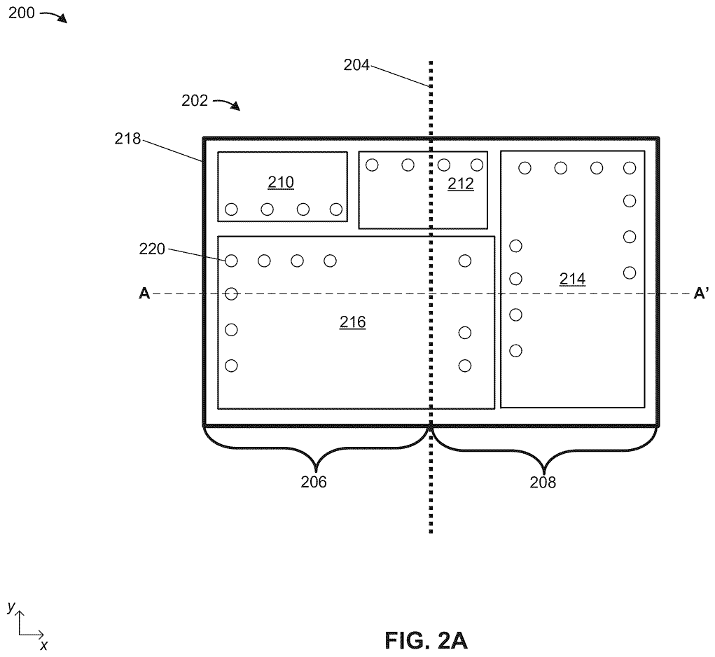

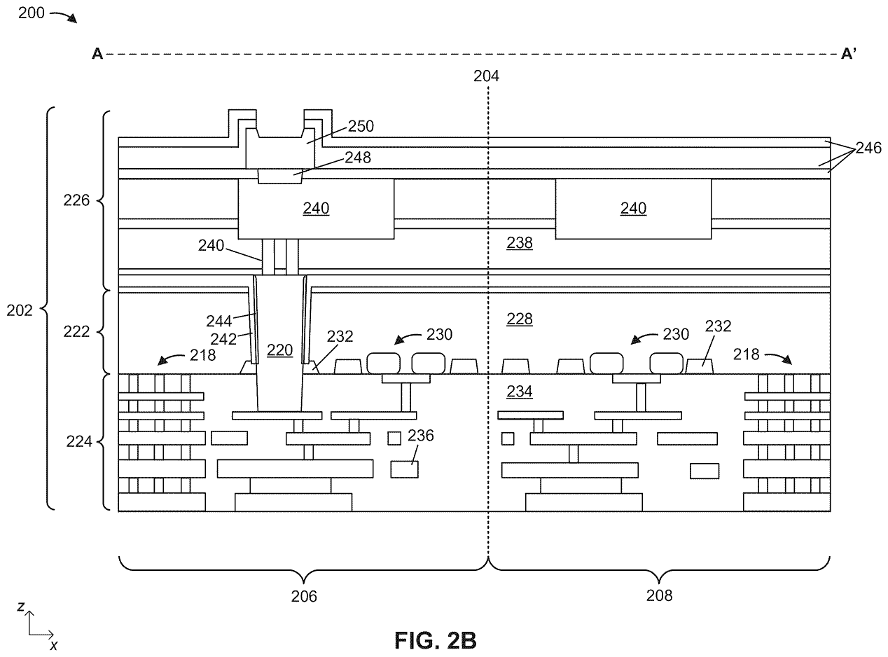

FIGS. 2A and 2B are diagrams of an example implementation 200 of a semiconductor device 202 described herein. FIG. 2A illustrates a top view of the semiconductor device 202, and FIG. 2B illustrates a cross-section view of the semiconductor device 202 along the line A-A′ in FIG. 2A.

As shown in FIG. 2A, the semiconductor device 202 may include an interface 204 between different lateral regions 206 and 208 of the semiconductor device 202. The lateral regions 206 and 208 may be laterally adjacent in an x-direction and/or in a y-direction in the semiconductor device 202, and may include different top view layouts of functional regions. For example, functional regions 210-216 may be laterally distributed across the lateral regions 206 and 208, where the functional region 210 is included in the lateral region 206, portions of the functional region 212 are included in the lateral regions 206 and 208, the functional region 214 is included in the lateral region 208, and portions of the functional region 216 are included in the lateral regions 206 and 208. The top view layout and the quantity, sizes, shapes, and/or arrangements of functional regions 210-216 in the semiconductor device 202 are examples, and other layouts, quantities, sizes, shapes, and/or arrangements are within the scope of the present disclosure.

The semiconductor device 202 may be a system-on-chip (SoC) die, a central processing unit (CPU) die, a graphics processing unit (GPU) die, a digital signal processing (DSP) die, an application specific integrated circuit (ASIC) die, an image sensor die, an HPC die, and/or another type of semiconductor die that includes a plurality of functional regions 210-216. Each of the functional regions 210-216 may be manufactured to include integrated circuits that are configured to perform a particular set of functions of the semiconductor device 202. For example, the functional region 210 may be a memory region (or a memory core) of the semiconductor device 202 that includes integrated circuitry configured to perform memory functions of the semiconductor device 202. As another example, the functional region 212 may be an analog circuitry region (or an analog core) of the semiconductor device 202 that includes integrated circuitry configured to perform analog functions of the semiconductor device 202. As another example, the functional region 214 may be an RF circuitry region (or an RF core) of the semiconductor device 202 that includes integrated circuitry configured to perform RF communication functions of the semiconductor device 202. As another example, the functional region 216 may be a logic circuitry region (or a logic core) of the semiconductor device 202 that includes integrated circuitry configured to perform logic functions of the semiconductor device 202. In some implementations, the semiconductor device 202 includes another type of functional region or a different combination of functional regions.

The lateral regions 206 and 208 are regions of the semiconductor device 202 that were patterned by different sets of reticles 108 of the lithography system 100 during manufacturing of the semiconductor device 202. For example, one or more layers and/or structures of the lateral region 206 may be patterned using a first set of reticles 108, and one or more layers and/or structures of the lateral region 208 may be patterned using a second set of reticles 108. The first set of reticles and the second set of reticles 108 may be used sequentially to form different layouts in the lateral regions 206 and 208 from the same layer formed across the semiconductor device 202. The interface 204 may correspond to a boundary between the area (e.g., the lateral region 206) that was patterned using the first set of reticles 108, and the area (e.g., the lateral region 208) that was patterned using the second set of reticles 108. Thus, one or more of the functional regions 210-216, such as the functional region 210, are formed using only the first set of reticles 108. One or more of the functional regions 210-216, such as the functional region 214, are formed using only the second set of reticles 108. One or more of the functional regions 210-216, such as the functional regions 212 and 216, are formed using both the first and second sets of reticles 108. For example, the first set of reticles 108 may be used to form the portions of the functional regions 212 and 216 located in the lateral region 206, and the second set of reticles 108 may be used to form the portions of the functional regions 212 and 216 located in the lateral region 208.

This multiple-reticle exposure technique enables the lateral regions 206 and 208 of the semiconductor device 202 to be formed using a plurality of sets of reticles 108 so that the lateral footprint of the semiconductor device 202 may be expanded monolithically. In other words, the functional regions 210-216 may be formed on the same substrate using a plurality of sets of reticles 108 such that the functional regions 210-216 are integrated onto a single work piece, as opposed to the functional regions 210-216 being formed on separate work pieces and bonded together or otherwise integrated by wire-bonding on a package substrate. In some implementations, the multiple-reticle exposure technique enables the semiconductor device 202 to be formed as a monolithic “superchip” that has a lateral size of approximately 25 millimeters by approximately 30 millimeters, or greater.

As further shown in FIG. 2A, the semiconductor device 202 may include a seal ring structure 218 that laterally surrounds the functional regions 210-216 of the semiconductor device 202. The seal ring structure 218 may include a ring of interconnected layers of metallization structures and interconnect structures that provide increased structural rigidity for the semiconductor device 202, which may reduce the likelihood of cracking, warpage, and/or another type of physical damage that might otherwise result from physical stresses that are exerted on the semiconductor device 202. Additionally and/or alternatively, the interconnected layers of the seal ring structure 218 may be configured to provide a humidity seal for the semiconductor device 202, which may reduce the likelihood of humidity ingress in the semiconductor package.

The seal ring structure 218 may include a plurality of segments, including a first set of segments around the perimeter of the lateral region 206 and a second set of segments around the perimeter of the lateral region 208. The first set of segments and the second set of segments may be connected together to form a continuous seal around the perimeter of the semiconductor device 202.

As further shown in FIG. 2A, the semiconductor device 202 also includes one or more through-substrate interconnect structures 220. A through-substrate interconnect structure 220 may be included in one or more of the functional regions 210-216. A through-substrate interconnect structure 220 may extend through a substrate layer of the semiconductor device 202 and may electrically connect a frontside and a backside of the semiconductor device 202. In this way, the through-substrate interconnect structures 220 enable signals and/or power to be provided between the frontside and the backside of the semiconductor device 202. A through-substrate interconnect structure 220 may include a through-silicon via (TSV), a metal pillar, a metal column, and/or other another type of vertically (e.g., in the z-direction) elongated conductive structure.

As shown in FIG. 2B, the semiconductor device 202 may include a device layer 222, a frontside interconnect layer 224 on a first side (e.g., a frontside) of the device layer 222, and a backside interconnect layer 226 on a second side (e.g., a backside) of the device layer. The frontside interconnect layer 224, the device layer 222, and the backside interconnect layer 226 may be vertically arranged in the z-direction in the semiconductor device 202.

The device layer 222 may include a substrate layer 228. The substrate layer 228 may correspond to a portion of a semiconductor wafer on which the semiconductor device 202 was formed. The substrate layer 228 may include a silicon (Si) substrate, a substrate formed of a material including silicon, a III-V compound semiconductor material substrate such as gallium arsenide (GaAs), a silicon-on-insulator (SOI) substrate, or another type of semiconductor substrate.

The device layer 222 may further include one or more integrated circuit devices 230 in and/or on the frontside of the substrate layer 228. The integrated circuit devices 230 may each include transistors (e.g., planar transistors, fin field effect transistors (finFETs), gate all around (GAA) transistors), pixel sensors, capacitors, resistors, inductors, photodetectors, transceivers, transmitters, receives, optical circuits, diodes, and/or other types of passive and/or active integrated circuit devices.

The lateral regions 206 and 208 may include different arrangements of integrated circuit devices 230 that were formed using different sets of reticles 108. The integrated circuit devices 230 in the lateral region 206 may be arranged in integrated circuits that implement the functionality of the functional regions 210, 212, and 216. Similarly, the integrated circuit devices 230 in the lateral region 208 may be arranged in integrated circuits that implement the functionality of the functional regions 212, 214, and 216.

Isolation regions 232 may also be included in the substrate layer 228 to provide electrical isolation for the integrated circuit devices 230. One or more isolation regions 232 may include implant regions of the substrate layer 228 in which dopants were implanted. The dopants may include, for example n-type dopants (such as phosphorous (P) and/or arsenic (As)) and/or p-type dopants (such as boron (B)). Additionally and/or alternatively, one or more of the isolation regions 232 may include shallow trench isolation (STI) structures. An STI structure may be a dielectric structure that extends into the frontside of the substrate layer 228, and may include one or more dielectric materials such as a silicon oxide material (SiOₓ such as SiO₂), a silicon nitride material (SixNy such as Si₃N₄), and/or another suitable dielectric material.

The frontside interconnect layer 224 includes one or more dielectric layers 234 that may be arranged in a direction (e.g., the z-direction) that is approximately perpendicular to the substrate layer 228. The dielectric layer(s) 234 may include backend dielectric layers (e.g., interlayer dielectric (ILD) layers, intermetal dielectric (IMD) layers) and etch stop layers (ESLs) that are arranged in an alternating manner in the frontside interconnect layer 224. The dielectric layer(s) 234 may each include an oxide (e.g., a silicon oxide (SiOx) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SixNy), silicon carbide (SiC), silicon oxynitride (SiON), and/or another suitable dielectric material.

The frontside interconnect layer 224 further includes one or more layers of conductive structures 236 (e.g., electrically conductive structures) in the dielectric layer(s) 234. The conductive structures 236 may be electrically coupled and/or physically coupled with one or more of the integrated circuit devices 230 in the device layer 222, and/or may be electrically interconnected together in the interconnect layer 224. The conductive structures 236 may correspond to circuit routing that enables signals and/or power to be provided to and/or from the integrated circuit devices 230. The conductive structures 236 may include a combination of conductive structures that extend primarily horizontally in the frontside interconnect layer 224 (e.g., trenches, conductive lines) and that are interconnected by interconnect structures (e.g., vias) that extend primarily vertically in the frontside interconnect layer 224. The conductive structures 236 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The layers of conductive structures 236 of the frontside interconnect layer 224 may be arranged in a vertical manner to facilitate electrical signals and/or power to be routed between the device layer 222 and external connectors coupled to the semiconductor device 202. The conductive structures 236 may be arranged in alternating layers of metallization layers (referred to as “M”-layers) and via layers (referred to as “V”-layers). Each metallization layer may include one or more conductive structures laterally arranged in the frontside interconnect layer 224, and each via layer may include one or more interconnect structures that interconnect the metallization layers in the frontside interconnect layer 224.

As an example, a metal-0 (M0) layer may be located at the bottom of the frontside interconnect layer 224 (e.g., interfacing the frontside of the device layer 222) and may be coupled with the integrated circuit devices 230 in the substrate layer 228, a via-0 (V0) layer may be located above and coupled with the MO layer in the frontside interconnect layer 224, a metal-1 (M1) layer may be located above and coupled with the VO layer in the frontside interconnect layer 224, a via-1 (V1) layer may be located above and coupled with the M1 layer in the frontside interconnect layer 224, a metal-2 (M2) layer may be located above and electrically coupled with the V1 layer in the frontside interconnect layer 224, and so on. In some implementations, the frontside interconnect layer 224 includes nine (9) stacked metallization layers (e.g., M0-M8). In other implementations, the contact layer (referred to as “CO”-layer) may be located at the bottom of the frontside interconnect layer 224 and may be coupled with the integrated circuit devices 230 in the substrate layer 228, a metal-1 (M1) layer may be located above and coupled with the CO layer in the frontside interconnect layer 224, and so on. In some implementations, the frontside interconnect layer 224 includes another quantity of stacked metallization layers.

The lateral regions 206 and 208 may include different arrangements of conductive structures 236 that were formed using different sets of reticles 108. The conductive structures 236 in the lateral region 206 may be arranged to distribute signals and/or power for the integrated circuits in the functional regions 210, 212, and 216. Similarly, the conductive structures 236 in the lateral region 208 may be arranged to distribute signals and/or power for the integrated circuits in the functional regions 212, 214, and 216. In some implementations, the conductive structures 236 in the lateral regions 206 and/or 208 may be arranged to distribute signals and/or power between two or more of the functional regions 210-216.

The seal ring structure 218 may also be located in the dielectric layer(s) 234 of the frontside interconnect layer 224. The seal ring structure 218 may include a plurality of vertically-arranged layers (e.g., in the z-direction) of conductive structures 236 that laterally surround the semiconductor device 202. In some implementations, the seal ring structure 218 extends into the substrate layer 228 of the device layer 222 of the semiconductor device 202. For example, additional isolation regions 232 may be included in the substrate layer 228 such that the additional isolation regions 232 are vertically adjacent to the layers of conductive structures 236 of the seal ring structure 218. This extends the electrical isolation provided by the seal ring structure 218 into the device layer 222.

The backside interconnect layer 226 includes one or more dielectric layers 238 that may be arranged in a direction (e.g., the z-direction) that is approximately perpendicular to the substrate layer 228. The dielectric layer(s) 238 may include backend dielectric layers (e.g., ILD layers, IMD layers) and ESLs that are arranged in an alternating manner in the backside interconnect layer 226. The dielectric layer(s) 238 may each include an oxide (e.g., a silicon oxide (SiOx) and/or another oxide material), an undoped silicate glass (USG), a boron-containing silicate glass (BSG), a fluorine-containing silicate glass (FSG), an ELK dielectric material having a dielectric constant that is less than approximately 2.5, a silicon nitride (SixNy), silicon carbide (SiC), silicon oxynitride (SiON), and/or another suitable dielectric material.

The backside interconnect layer 226 further includes one or more layers of conductive structures 240 (e.g., electrically conductive structures) in the dielectric layer(s) 238. The conductive structures 240 may be electrically coupled and/or physically coupled to one or more through-substrate interconnect structures 220 that extend through the device layer 222 between the frontside interconnect layer 224 and the backside interconnect layer 226.

The lateral regions 206 and 208 may include different arrangements of conductive structures 240 that were formed using different sets of reticles 108. The conductive structures 240 in the lateral region 206 may be arranged to distribute signals and/or power for the integrated circuits in the functional regions 210, 212, and 216. Similarly, the conductive structures 240 in the lateral region 208 may be arranged to distribute signals and/or power for the integrated circuits in the functional regions 212, 214, and 216. In some implementations, the conductive structures 240 in the lateral regions 206 and/or 208 may be arranged to distribute signals and/or power between two or more of the functional regions 210-216.

In this way, multiple-reticle exposure techniques may be used for frontside processing and backside processing when manufacturing the semiconductor device 202.

Frontside processing of the semiconductor device 202 may include using different sets of reticles 108 to form different circuit layouts in and/or above the frontside of the device layer 222 (including in the frontside interconnect layer 224) in the lateral regions 206 and 208.

Backside processing of the semiconductor device 202 may include using different sets of reticles 108 to form different circuit layouts in and/or above the backside of the device layer 222 (including in the backside interconnect layer 226) in the lateral regions 206 and 208.

Thus, the lateral region 206 may include a frontside region (or frontside portion) and a backside region (or backside portion), and the lateral region 208 may include a frontside region (or frontside portion) and a backside region (or backside portion).

As further shown in FIG. 2B, a through-substrate interconnect structure 220 may extend through an isolation region 232 that is included in the substrate layer 228. The through-substrate interconnect structure 220 may include one or more electrically conductive materials, such as copper (Cu), gold (Au), silver (Ag), nickel (Ni), tin (Sn), ruthenium (Ru), cobalt (Co), tungsten (W), titanium (Ti), aluminum copper (AlCu), one or more metals, one or more conductive ceramics, alloys thereof, and/or another type of electrically conductive material.

The material(s) of the through-substrate interconnect structure 220 may be susceptible to diffusion into the surrounding substrate layer 228. Accordingly, one or more liners 242, 244 may be included between the through-substrate interconnect structure 220 and the substrate layer 228 to provide a diffusion barrier and/or to promote adhesion between the through-substrate interconnect structure 220 and the substrate layer 228, among other examples. Moreover, in some implementations, an additional barrier layer is deposited on the one or more liners 242, 244 to further suppress metal diffusion from the through-substrate interconnect structure 220 more effectively. The one or more liners 242, 244 may include a high-k dielectric liner, a low-k dielectric liner, and/or another type of liner. In some implementations, a plurality of liners 242, 244 are included between the through-substrate interconnect structure 220 and the substrate layer 228. The barrier layer, if included, may include diffusion blocking materials such as tantalum (Ta) and/or tantalum nitride (TaN), among other examples.

A high-k dielectric liner may include one or more high-k dielectric materials, such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOx such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAIO₃), among other examples. A low-k dielectric liner may include one or more low-k dielectric materials, such as a silicon oxide (SiOₓ), an undoped silicate glass (USG), a boron-containing silicate glass (BSG), and/or a fluorine-containing silicate glass (FSG), among other examples.

As further shown in FIG. 2B, one or more passivation layers 246 may be included on the backside of the device layer 222 above the dielectric layer(s) 238. The passivation layer(s) 246 may include silicon nitride (SiₓN_{y}), tantalum nitride (TaN), silicon oxide (SiOₓ), and/or another suitable passivation material. The passivation layers 246 may be included to passivate the backside of the semiconductor device 202 and/or for patterning the backside of the semiconductor device 202 for formation of connection pads 248 and connection structures 250 over the backside of the semiconductor device 202. The connection pads 248 may include copper (Cu) pads, aluminum (Al) pads, aluminum copper (AlCu) pads, and/or another type of metal pads that provide a surface on which the connection structures 250 may be formed. The connection structures 250 enable the semiconductor device 202 to be attached to a substrate (e.g., an interposer, a printed circuit board (PCB)), another semiconductor package, and/or to be attached to another structure. The connection structures 250 may include solder pads, solder balls, micro-bumps, and/or another type of connection structures.

As indicated above, FIGS. 2A and 2B are provided as an example. Other examples may differ from what is described with regard to FIGS. 2A and 2B.

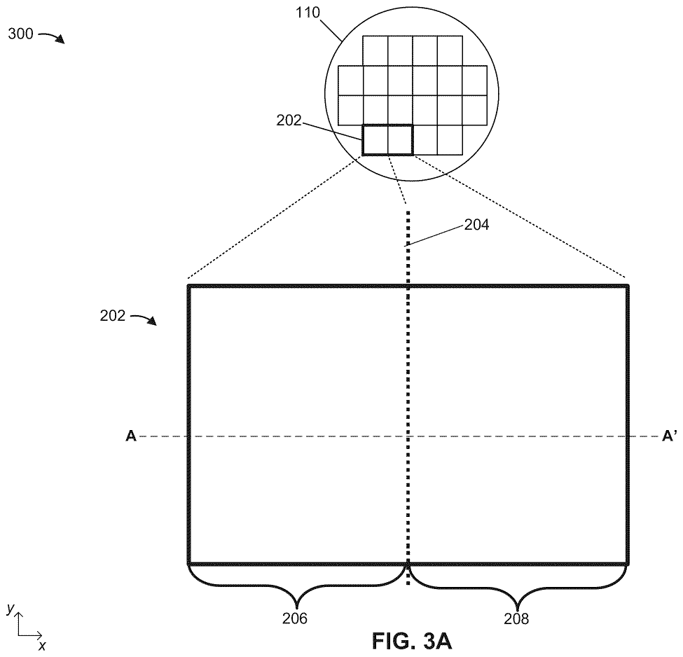

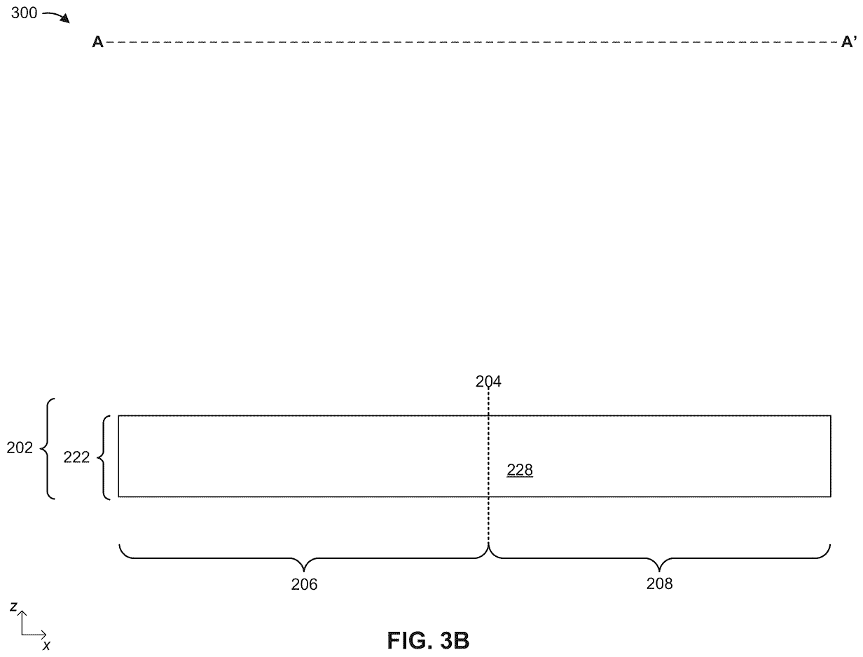

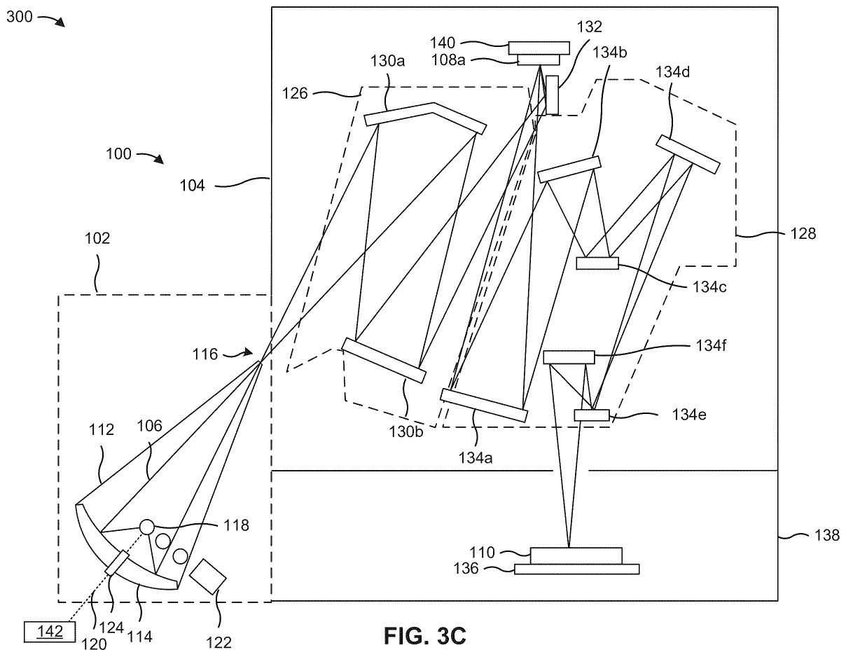

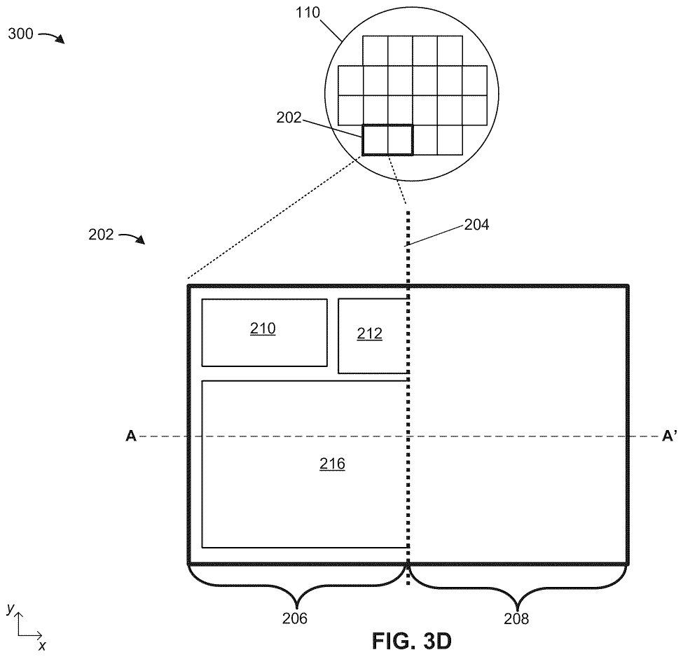

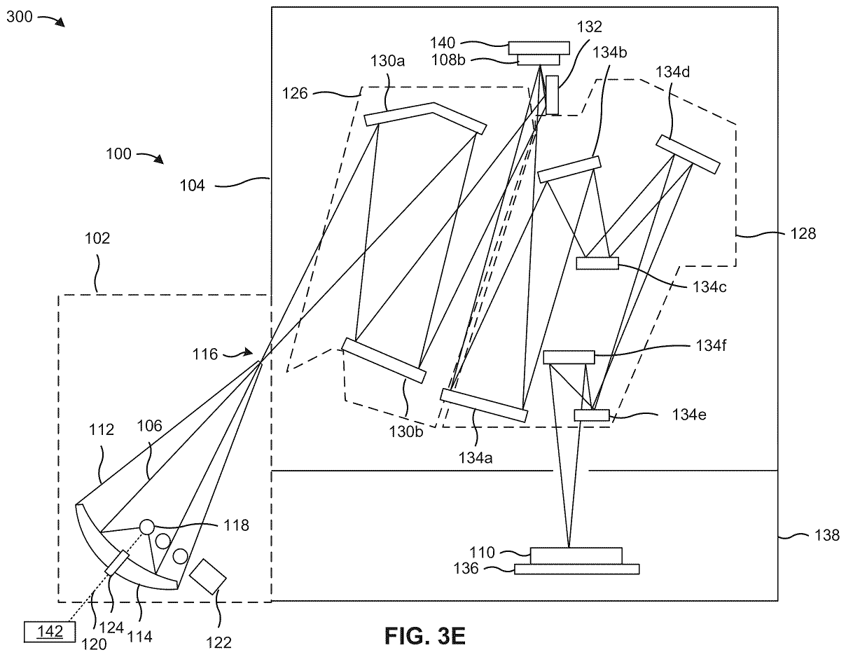

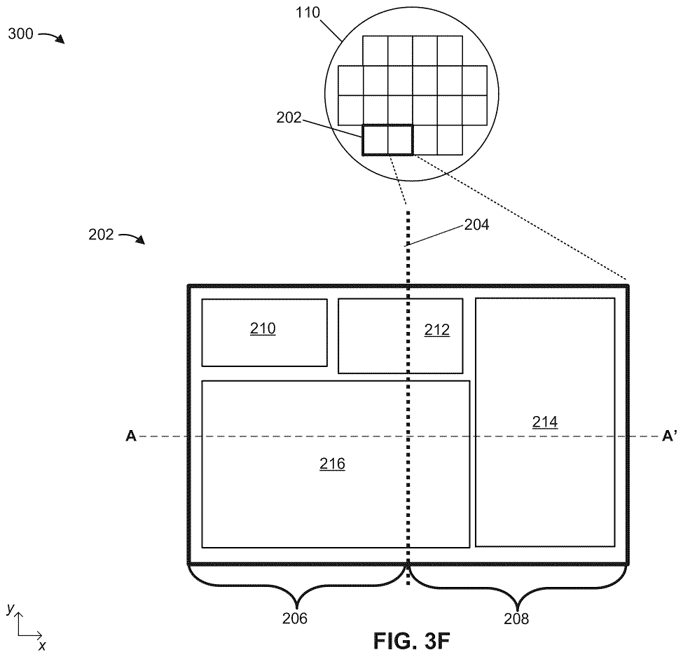

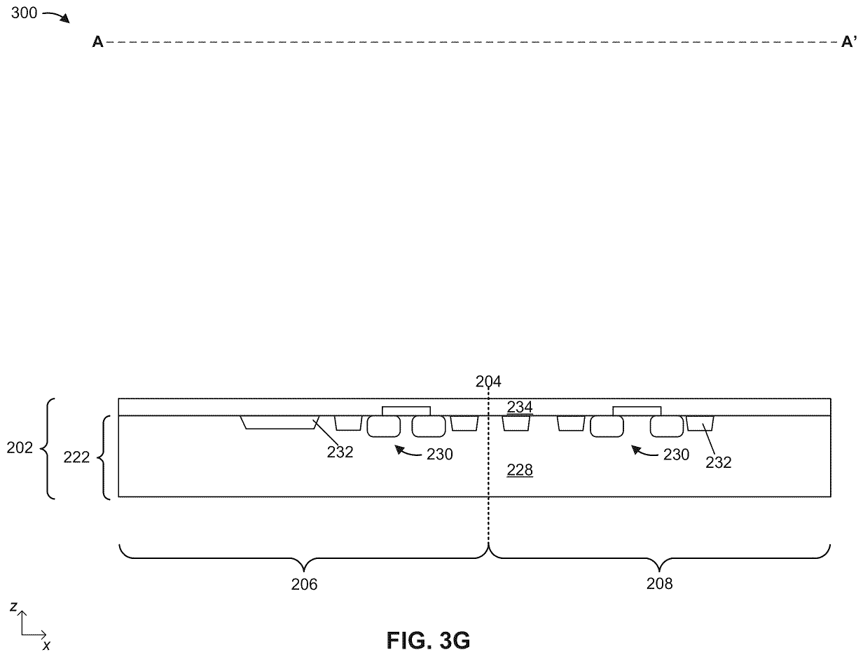

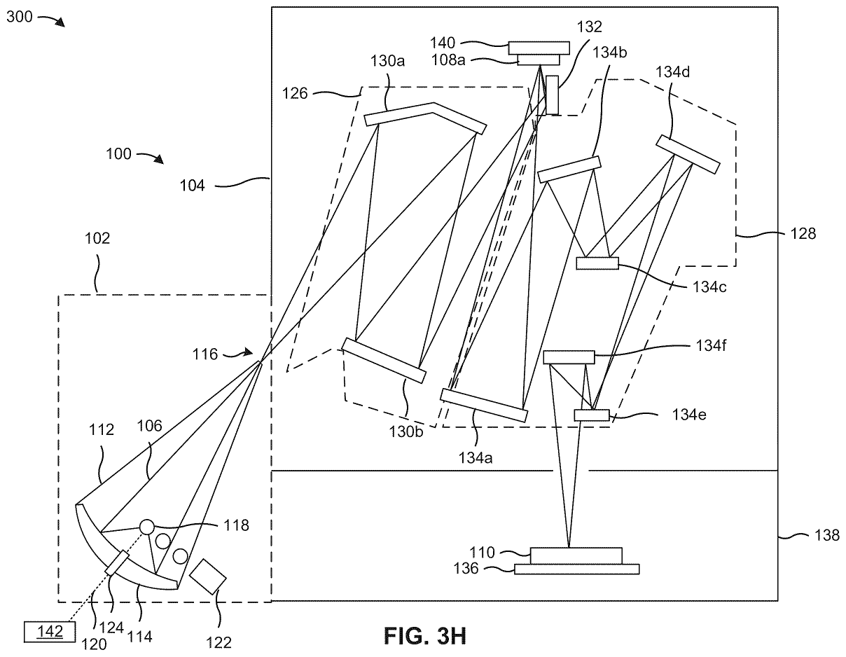

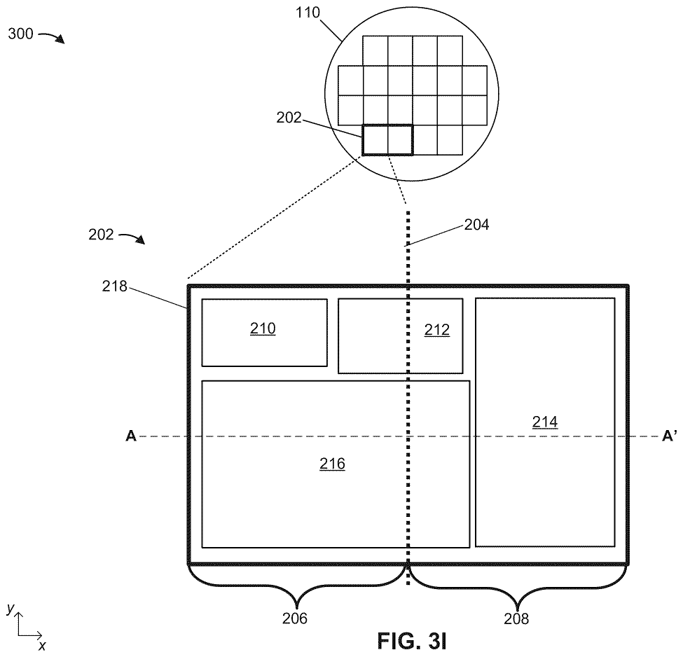

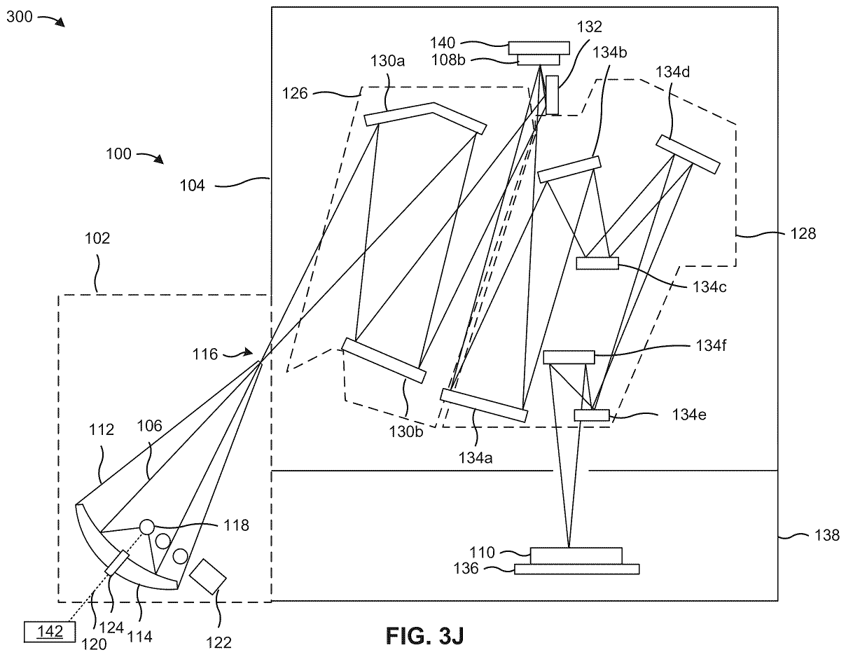

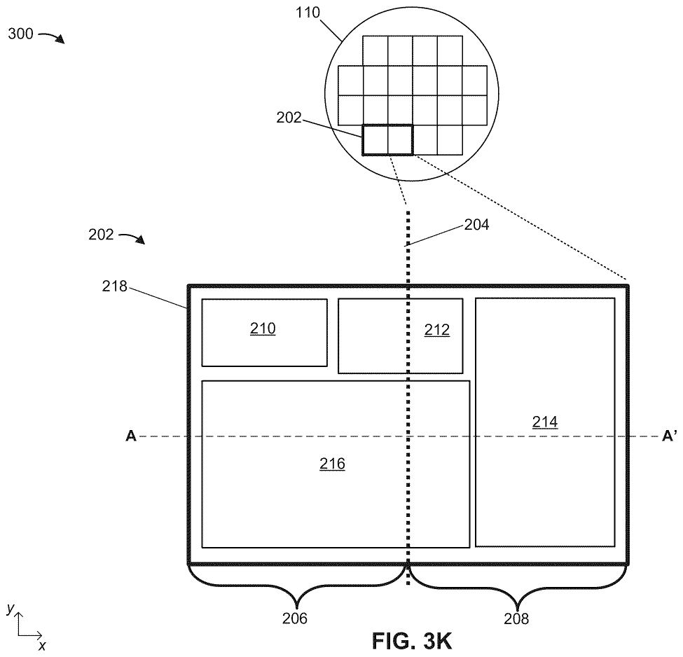

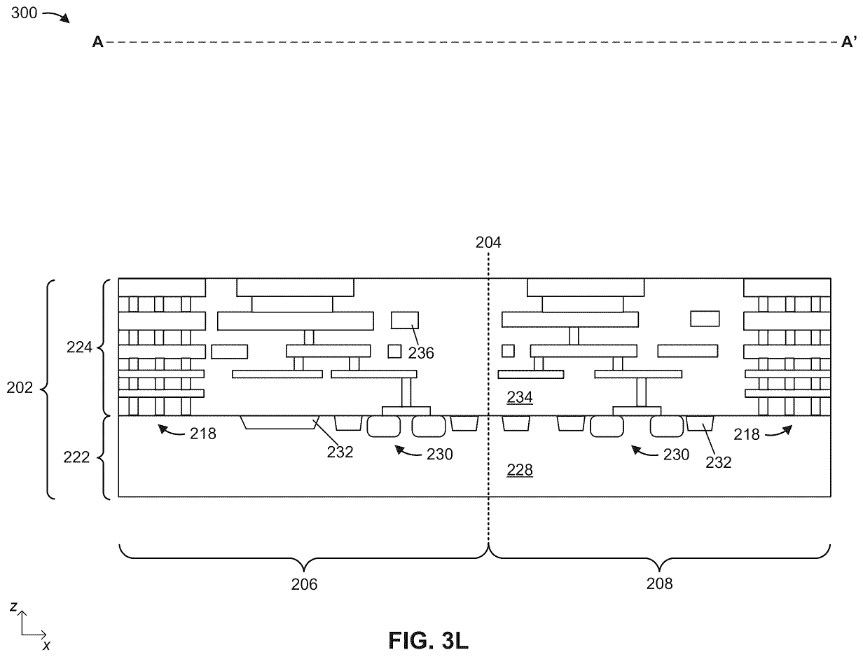

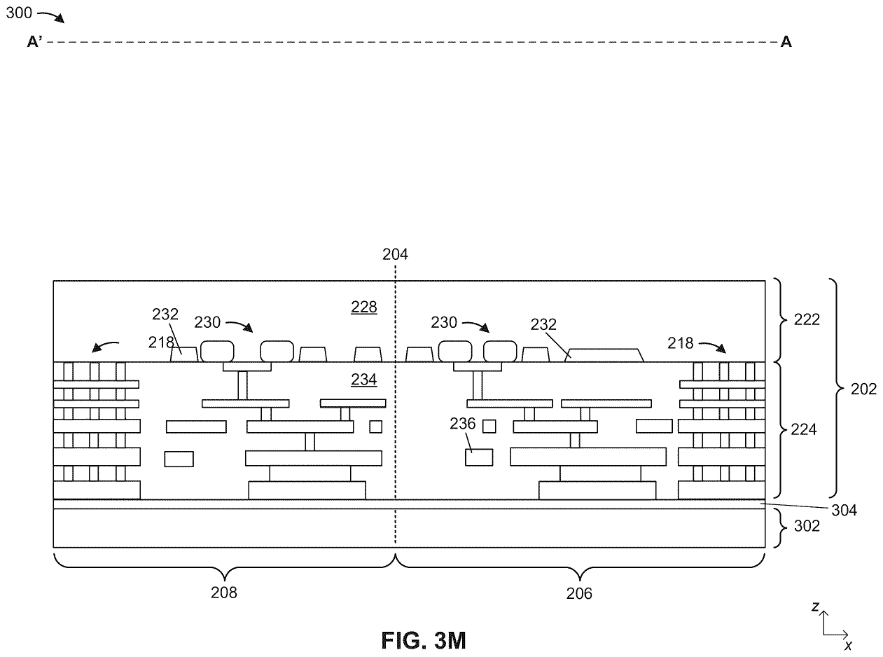

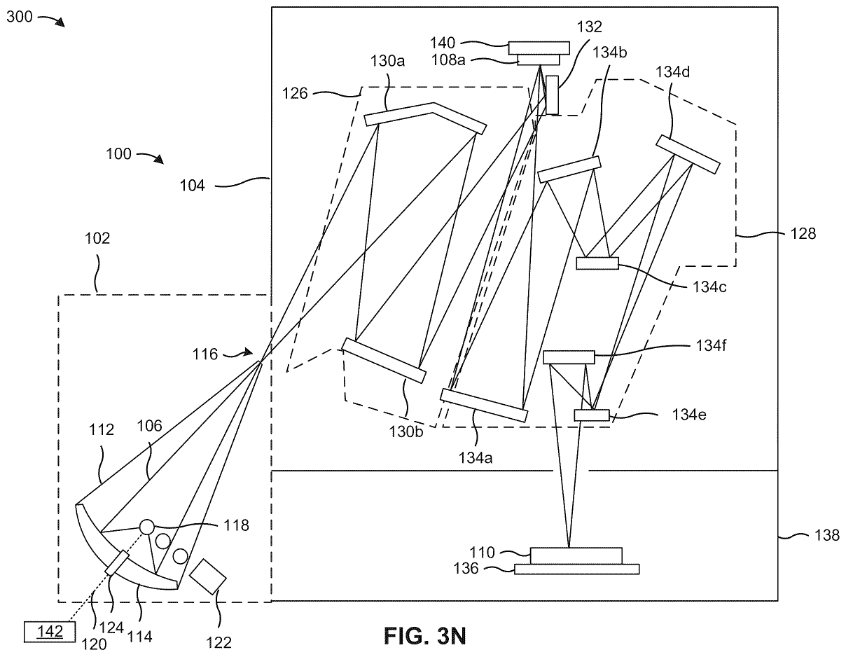

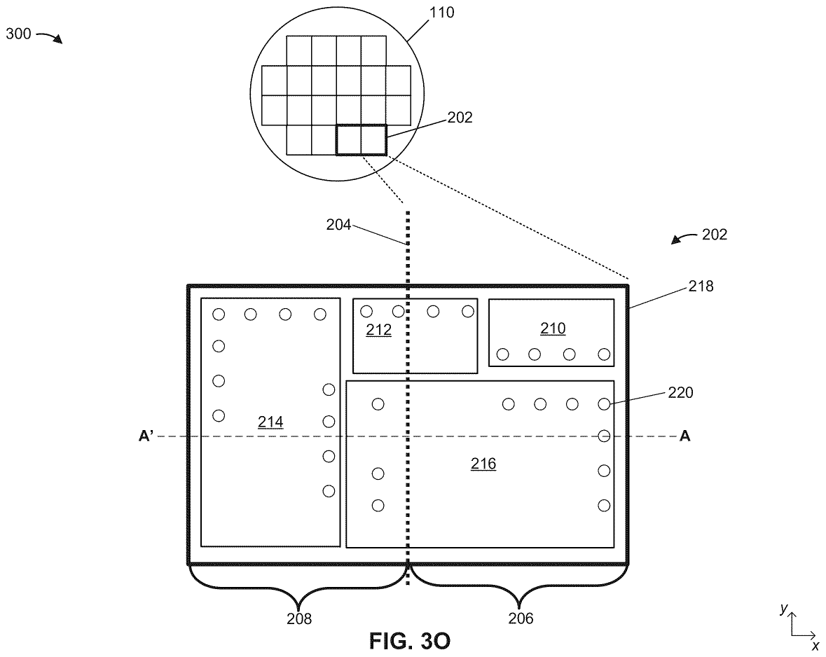

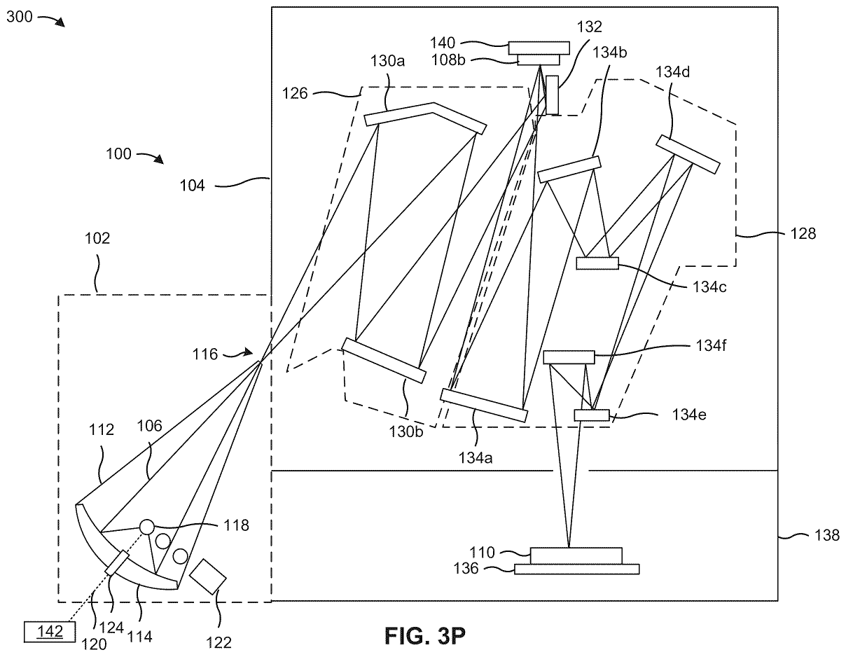

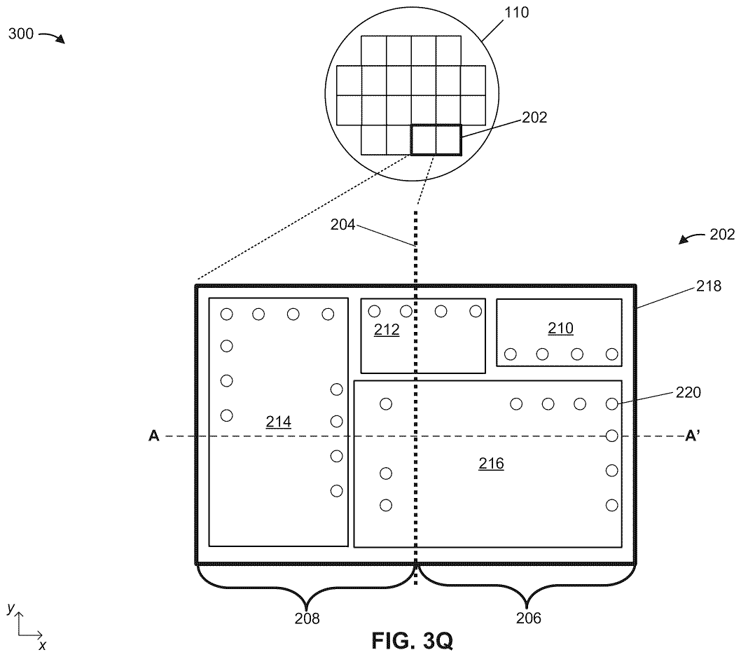

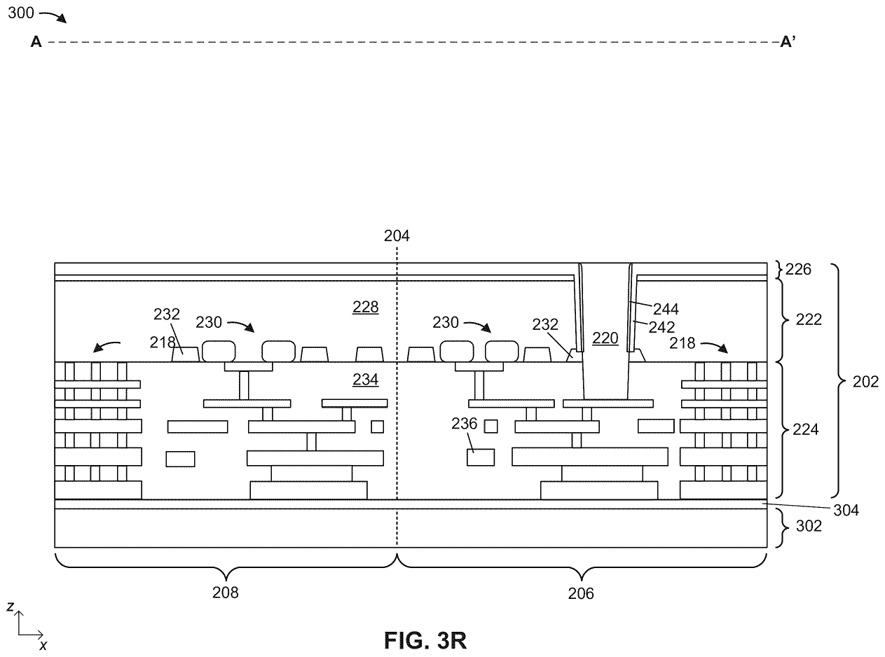

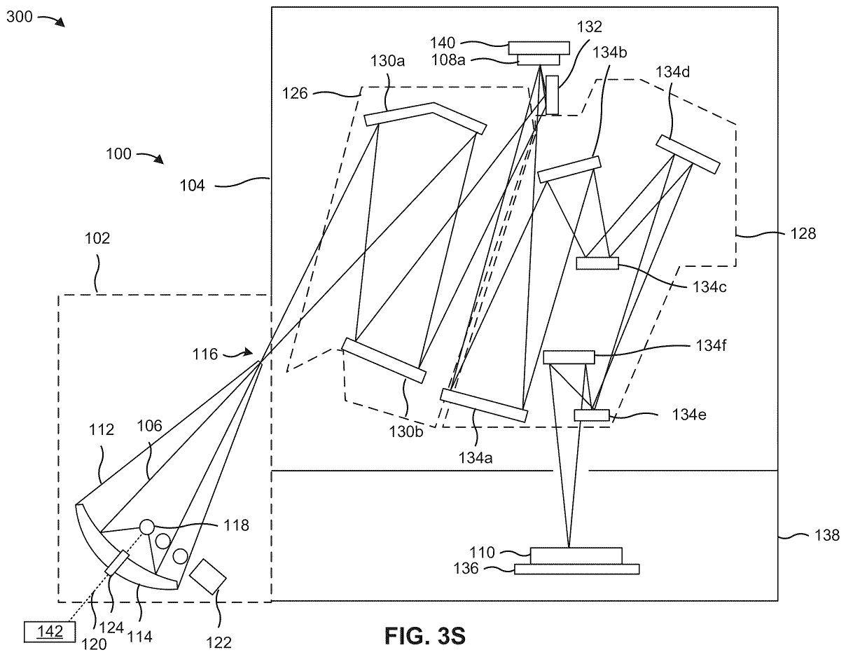

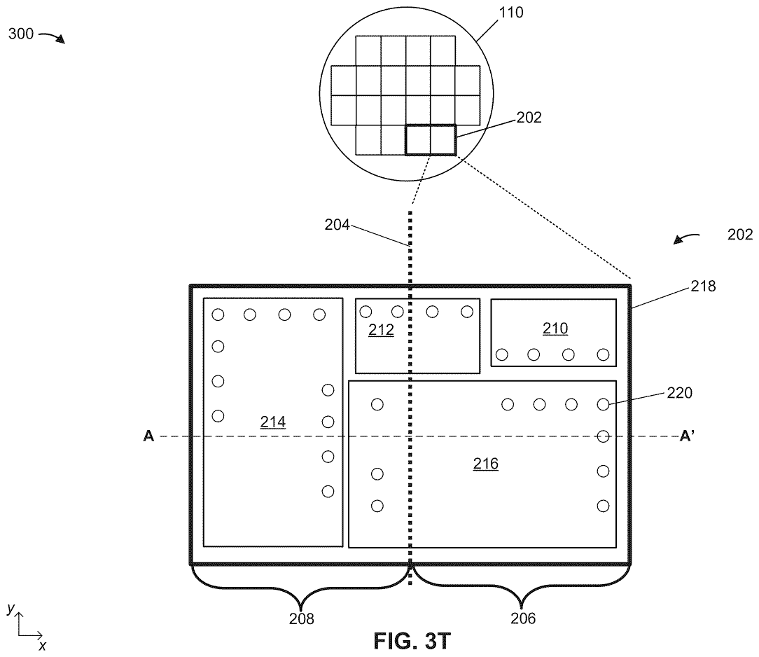

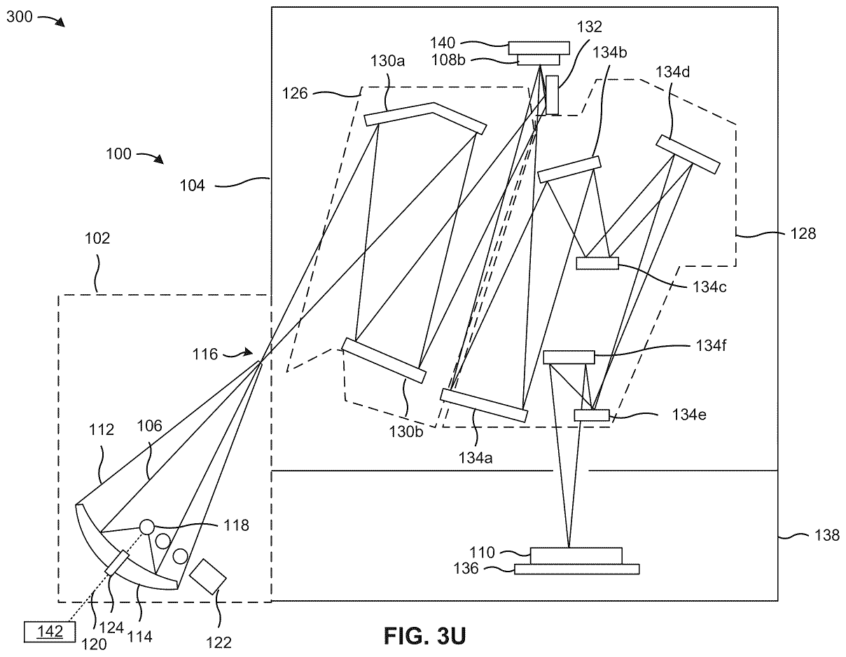

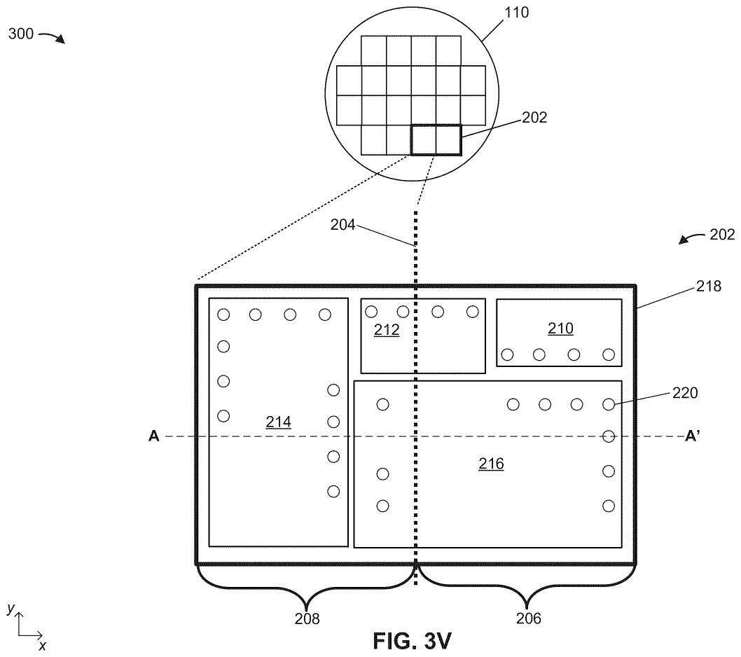

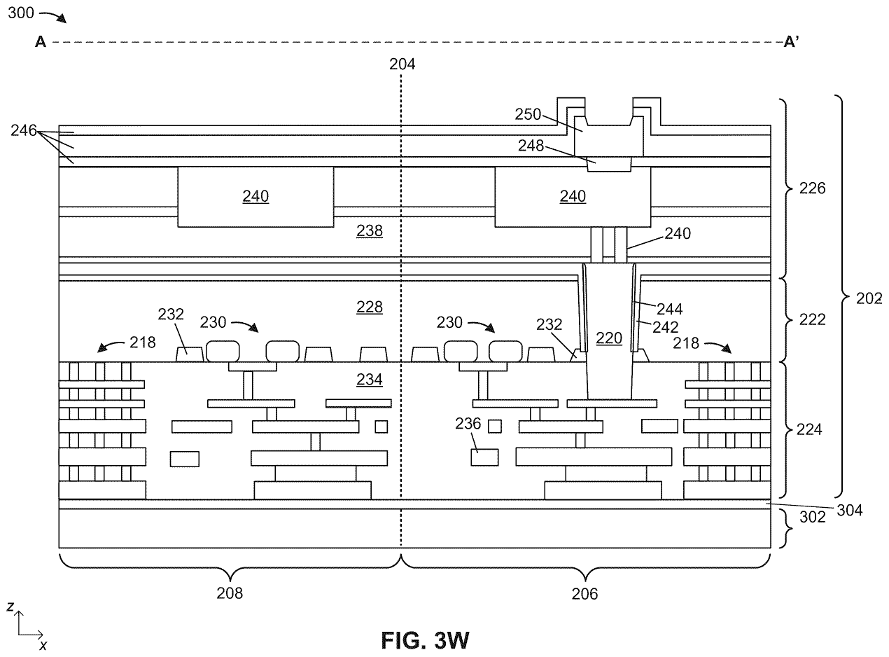

FIGS. 3A-3W are diagrams of an example implementation 300 of forming the semiconductor device 202 described herein. The example implementation 300 includes the use of multiple-reticle exposure techniques to form different layouts on the frontside and on the backside of the semiconductor devices 202 in different lateral regions 206 and 208 using different sets of reticles 108. In some implementations, one or more semiconductor processing tools, such as a deposition tool, an exposure tool (e.g., the lithography system 100), a developer tool, an etch tool, an ion implantation tool, a bonding tool, a planarization tool, and/or another type of semiconductor processing tool, may be used to perform one or more operations described in connection with FIGS. 3A-3W.

As shown in FIG. 3A, the semiconductor device 202 may be fabricated on a semiconductor wafer 110 along with a plurality of other semiconductor devices 202. The operations and/or techniques described in connection with FIGS. 3A-3W may be performed and/or used at the wafer level, meaning that the operations and/or techniques described in connection with FIGS. 3A-3W may be performed and/or used to manufacture a plurality of semiconductor devices 202 formed on the same semiconductor wafer 110.

As shown in FIG. 3B, the substrate layer 228 of the device layer 222 of the semiconductor device 202 may correspond to a portion of the semiconductor wafer 110 on which the semiconductor device 202 is fabricated.

As shown in FIGS. 3C-3G, a multiple-reticle exposure technique may be used to pattern and form different integrated circuit layouts in the lateral regions 206 and 208 on the frontside of the device layer 222 of the semiconductor device 202. For example, and as shown in FIGS. 3C and 3D, a set of reticles 108a may be used to pattern the frontside of the device layer 222 in the lateral region 206 to form an arrangement of integrated circuit devices 230 and isolation regions 232 in and/or on the frontside of the device layer 222 of the semiconductor device 202 in the lateral region 206. As shown in FIGS. 3E and 3F, a set of reticles 108b may be used to pattern the frontside of the device layer 222 in the lateral region 208 to form an arrangement of integrated circuit devices 230 and isolation regions 232 in and/or on the frontside of the device layer 222 of the semiconductor device 202 in the lateral region 208.

In some implementations, a deposition tool may be used to form the photoresist layer on the substrate layer 228 in the lateral regions 206 and 208. The uses of the sets of reticles 108a and 108b may be sequential. For example, the semiconductor wafer 110 may be placed on the wafer stage 136 of the lithography system 100, a first reticle 108a may be loaded into the reticle stage 140 of the lithography system 100 as shown in FIG. 3C, and the first reticle 108a may be used to perform a first exposure operation to pattern the frontside of the substrate layer 228 in the lateral region 206 to form an arrangement of recesses for the isolation regions 232 in the lateral region 206. The first reticle 108a may be removed from the reticle stage 140 and replaced with a first reticle 108b as shown in FIG. 3E, and the first reticle 108b may be used to perform a second exposure operation (e.g., after the first exposure operation) to pattern the frontside of the substrate layer 228 in the lateral region 208 to form an arrangement of recesses for the isolation regions 232 in the lateral region 208. In some implementations, a developer tool may be used to develop and remove portions of the photoresist layer to expose the pattern in the lateral regions 206 and 208. An etch tool may be used to etch the substrate layer 228 based on the pattern to form the recesses in the lateral regions 206 and 208. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique) in the lateral regions 206 and 208. A deposition tool may be used to deposit dielectric material in the recesses in the lateral regions 206 and 208 using a chemical vapor deposition (CVD) technique, a physical vapor deposition (PVD) technique, an atomic layer deposition (ALD) technique, and/or another suitable deposition technique. A planarization tool may be used to planarize the isolation regions 232.

As another example, a layer of gate material may be deposited (e.g., by CVD, ALD, PVD, electroplating) over the frontside of the substrate layer 228. The semiconductor wafer 110 may be placed on the wafer stage 136 of the lithography system 100, a second reticle 108a may be loaded into the reticle stage 140 of the lithography system 100 as shown in FIG. 3C, and the second reticle 108a may be used to perform a third exposure operation (e.g., after the second exposure operation) to pattern the layer of gate material over of the substrate layer 228 in the lateral region 206 to form an arrangement of gate structures of the integrated circuit devices 230 in the lateral region 206. The second reticle 108a may be removed from the reticle stage 140 and replaced with a second reticle 108b as shown in FIG. 3E, and the second reticle 108b may be used to perform a fourth exposure operation (e.g., after the third exposure operation) to pattern the layer of gate material over of the substrate layer 228 in the lateral region 208 to form an arrangement of gate structures of the integrated circuit devices 230 in the lateral region 208.

As another example, a photoresist layer may be deposited over the frontside of the substrate layer 228. The semiconductor wafer 110 may be placed on the wafer stage 136 of the lithography system 100, a third reticle 108a may be loaded into the reticle stage 140 of the lithography system 100 as shown in FIG. 3C, and the third reticle 108a may be used to perform a fifth exposure operation (e.g., after the fourth exposure operation) to pattern the photoresist layer over of the substrate layer 228 in the lateral region 206 to form an implant mask in the lateral region 206. The third reticle 108a may be removed from the reticle stage 140 and replaced with a third reticle 108b as shown in FIG. 3E, and the third reticle 108b may be used to perform a sixth exposure operation (e.g., after the fifth exposure operation) to pattern the photoresist layer over of the substrate layer 228 in the lateral region 208 to form an implant mask in the lateral region 208. The implant masks in the lateral regions 206 and 208 may be used to respectively form source/drain regions and/or other doped regions of the integrated circuit devices 230 in the frontside of the substrate layer 228 (e.g., by ion implantation).

As shown in FIGS. 3H-3L, a multiple-reticle exposure technique may be used to pattern and form different metallization layouts in the lateral regions 206 and 208 above the frontside of the device layer 222 of the semiconductor device 202. For example, and as shown in FIGS. 3H and 3I, a set of reticles 108a may be used to pattern the frontside of the device layer 222 in the lateral region 206 to form an arrangement of conductive structures 236 and a portion of a seal ring structure 218 in the frontside interconnect layer 224 of the semiconductor device 202 in the lateral region 206. As shown in FIGS. 3J and 3K, a set of reticles 108b may be used to pattern the frontside of the device layer 222 in the lateral region 208 to form an arrangement of conductive structures 236 and a portion of a seal ring structure 218 in the frontside interconnect layer 224 of the semiconductor device 202 in the lateral region 208.

The uses of the sets of reticles 108a and 108b for forming the lateral regions 206 and 208 of the frontside interconnect layer 224 may be sequential. For example, a dielectric layer 234 of the frontside interconnect layer 224 may be deposited over the frontside of the device layer 222 of the semiconductor device 202. The semiconductor wafer 110 may be placed on the wafer stage 136 of the lithography system 100, a fourth reticle 108a may be loaded into the reticle stage 140 of the lithography system 100, and the fourth reticle 108a may be used to perform a seventh exposure operation (e.g., after the sixth exposure operation) to pattern the first dielectric layer 234 in the lateral region 206. The fourth reticle 108a may be removed from the reticle stage 140 and replaced with a fourth reticle 108b in the lithography system 100, and the fourth reticle 108b may be used to perform an eighth exposure operation (e.g., after the seventh exposure operation) to pattern the first dielectric layer 234 in the lateral region 208.

Patterning the first dielectric layer 234 in the lateral regions 206 and 208 may include patterning a photoresist layer or another type of patterning layer by performing the seventh and the eighth exposure operations, and then etching the first dielectric layer 234 (e.g., using an etch tool) based on the patterns formed in the lateral regions 206 and 208 in the photoresist layer to form recesses in the first dielectric layer 234. A layer of metal material may be deposited in the respective patterns of the lateral regions 206 and 208 to form different arrangements in a first layer of conductive structures 236 and in a first layer of the seal ring structure 218 in the lateral regions 206 and 208. Subsequent reticles 108a and 108b may be used in a similar sequential manner for patterning additional layers of conductive structures 236.

As shown in FIG. 3M, the semiconductor device 202 may be flipped to enable backside processing to be performed on the backside of the device layer 222 of the semiconductor device 202. The semiconductor wafer 110 on which the semiconductor device 202 is fabricated may be bonded to a carrier substrate 302 using a bonding dielectric layer 304 to protect the frontside of the semiconductor devices 202 formed on the semiconductor wafer 110.

As shown in FIGS. 3N-3R, a multiple-reticle exposure technique may be used to pattern and form different arrangements of through-substrate interconnect structures 220 in the lateral regions 206 and 208 from the backside of the device layer 222 of the semiconductor device 202. For example, and as shown in FIGS. 3N and 30, a set of reticles 108a may be used to pattern the backside of the device layer 222 in the lateral region 206 to form an arrangement of through-substrate interconnect structures 220 in the lateral region 206 of the semiconductor device 202. As shown in FIGS. 3P and 3Q, a set of reticles 108b may be used to pattern the backside of the device layer 222 in the lateral region 208 to form an arrangement of through-substrate interconnect structures 220 in the lateral region 208.

The uses of the sets of reticles 108a and 108b for forming the arrangements of through-substrate interconnect structures 220 in the lateral regions 206 and 208 from the backside of the device layer 222 may be sequential. For example, one or more patterning layers may be deposited over the backside of the device layer 222 of the semiconductor device 202. The semiconductor wafer 110 may be placed on the wafer stage 136 of the lithography system 100, a fifth reticle 108a may be loaded into the reticle stage 140 of the lithography system 100, and the fifth reticle 108a may be used to perform a ninth exposure operation (e.g., after the eighth exposure operation) to form a pattern in the patterning layers in the lateral region 206. The fifth reticle 108a may be removed from the reticle stage 140 and replaced with a fifth reticle 108b in the lithography system 100, and the fifth reticle 108b may be used to perform a tenth exposure operation (e.g., after the ninth exposure operation) to form a pattern in the patterning layers in the lateral region 208. An etch tool may be used to etch the substrate layer 228 in the lateral regions 206 and 208 based on the respective patterns formed in the patterning layers in the lateral regions 206 and 208 to form recesses that extend through the substrate layer 228 and into the frontside interconnect layer 224.

The liners 242, 244 may be formed on sidewalls of the recesses, and the recesses may be filled in with electrically conductive material (e.g., by CVD, PVD, ALD, and/or electroplating using a deposition tool) to form the through-substrate interconnect structures 220 in the recesses.

As shown in FIGS. 3S-3W, a multiple-reticle exposure technique may be used to pattern and form different metallization layouts in the lateral regions 206 and 208 above the backside of the device layer 222 of the semiconductor device 202. For example, and as shown in FIGS. 3S and 3T, a set of reticles 108a may be used to pattern the backside of the device layer 222 in the lateral region 206 to form an arrangement of conductive structures 240, connection pads 248, and connection structures 250 in the backside interconnect layer 226 of the semiconductor device 202 in the lateral region 206. As shown in FIGS. 3U and 3V, a set of reticles 108b may be used to pattern the backside of the device layer 222 in the lateral region 208 to form an arrangement of conductive structures 240, connection pads 248, and connection structures 250 in the backside interconnect layer 226 of the semiconductor device 202 in the lateral region 208.

The uses of the sets of reticles 108a and 108b for forming the lateral regions 206 and 208 of the backside interconnect layer 226 may be sequential. For example, a dielectric layer 238 of the backside interconnect layer 226 may be deposited over the backside of the device layer 222 of the semiconductor device 202. The semiconductor wafer 110 may be placed on the wafer stage 136 of the lithography system 100, a sixth reticle 108a may be loaded into the reticle stage 140 of the lithography system 100, and the sixth reticle 108a may be used to perform an eleventh exposure operation (e.g., after the tenth exposure operation) to pattern the first dielectric layer 238 in the lateral region 206. The sixth reticle 108a may be removed from the reticle stage 140 and replaced with a sixth reticle 108b in the lithography system 100, and the sixth reticle 108b may be used to perform a twelfth exposure operation (e.g., after the eleventh exposure operation) to pattern the first dielectric layer 238 in the lateral region 208.

Patterning the first dielectric layer 238 in the lateral regions 206 and 208 may include patterning a photoresist layer or another type of patterning layer by performing the eleventh and the twelfth exposure operations, and then etching the first dielectric layer 238 (e.g., using an etch tool) based on the patterns formed in the lateral regions 206 and 208 in the photoresist layer to form recesses in the first dielectric layer 238. A layer of metal material may be deposited in the recesses in the lateral regions 206 and 208 to form different arrangements in a first layer of conductive structures 240 in the lateral regions 206 and 208. Subsequent reticles 108a and 108b may be used in a similar sequential manner for patterning additional layers of conductive structures 240 in the backside interconnect layer 226.

As indicated above, FIGS. 3A-3W are provided as an example. Other examples may differ from what is described with regard to FIGS. 3A-3W.

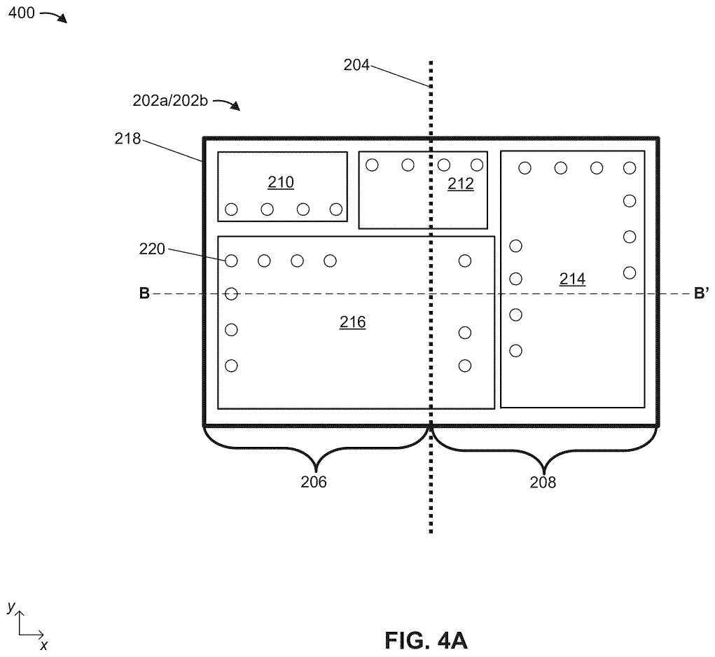

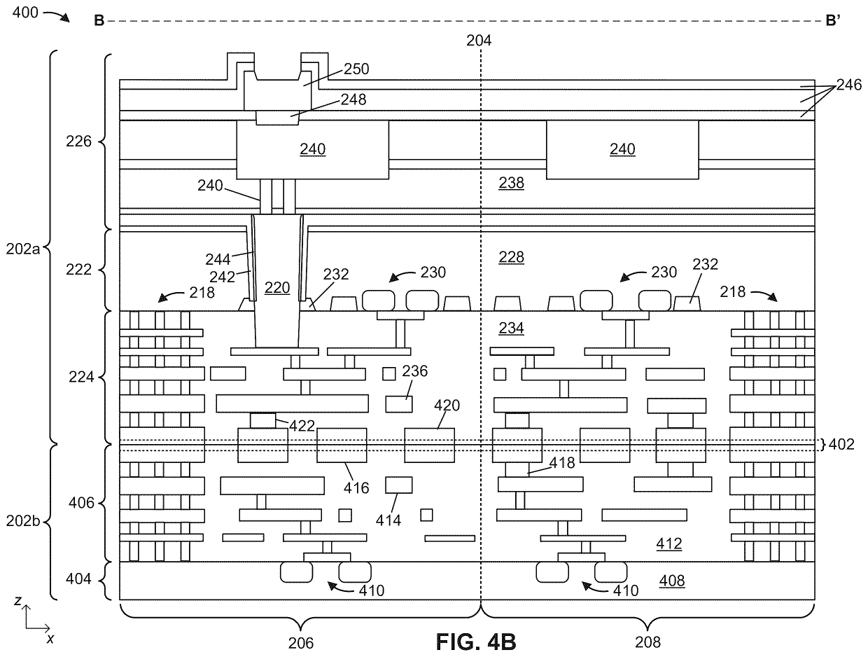

FIGS. 4A and 4B are diagrams of an example stacked semiconductor device 400 described herein. FIG. 4A illustrates a top view of the stacked semiconductor device 400, and FIG. 4B illustrates a cross-section view of the stacked semiconductor device 400 along the line B-B′ in FIG. 4A.

As shown in FIGS. 4A and 4B, the stacked semiconductor device 400 includes a plurality of semiconductor devices 202, such as a semiconductor device 202a and a semiconductor device 202b, that are stacked and vertically arranged in the z-direction. The stacked semiconductor device 400 may include the lateral regions 206 and 208 that may include respective lateral portions of the semiconductor device 202a and respective lateral portions of the semiconductor device 202b. Thus, the lateral region 206 of the stacked semiconductor device 400 may include a first portion of the semiconductor device 202a that is stacked together with a first portion of the semiconductor device 202b, and the lateral region 208 of the stacked semiconductor device 400 may include a second portion of the semiconductor device 202a that is stacked together with a second portion of the semiconductor device 202b. The functional regions 210-216 of the stacked semiconductor device 400 may be distributed across the semiconductor devices 202a and 202b.

As shown in FIG. 4B, the semiconductor devices 202a and 202b may be directly bonded together at a bonding interface 402. The semiconductor device 202b may include a device layer 404a and an interconnect layer 406 above the device layer 404. The semiconductor devices 202a and 202b may be bonded together such that the frontside interconnect layer 224 and the interconnect layer 406 are facing each other. Alternatively, the semiconductor devices 202a and 202b may be bonded together such that the backside interconnect layer 226 and the interconnect layer 406 are facing each other.

The device layer 404 may include a substrate layer 408 (e.g., similar to the substrate layer 228) and integrated circuit devices 410 (e.g., similar to the integrated circuit devices 230) in and/or on the substrate layer 408. The interconnect layer 406 may include one or more dielectric layers 412 (e.g., similar to the dielectric layer(s) 234) and one or more layers of conductive structures 414 (e.g., similar to the conductive structures 236) in the dielectric layer(s) 412. The seal ring structure 218 may extend through the interconnect layer 406 and may include one or more layers of conductive structures 414.

The interconnect layer 406 may include a plurality of bonding pads 416. The bonding pads 416 may be electrically coupled to the conductive structures 414 in the interconnect layer 406 by bonding vias 418 and/or other types of conductive structures. The bonding pads 416 and bonding vias 418 may each include tungsten (W), cobalt (Co), ruthenium (Ru), titanium (Ti), aluminum (Al), copper (Cu), gold (Au), and/or a combination thereof, among other examples of electrically conductive metals. In some implementations, one or more bonding pads 416 are each coupled to a single bonding via 418. In some implementations, one or more bonding pads 416 are each coupled to two or more bonding vias 418.

At the bonding interface 402, the bonding pads 416 of the semiconductor device 202b may be directly bonded together with bonding pads 420 in the frontside interconnect layer 224 of the semiconductor device 202a by metal-to-metal bonds. Moreover, a dielectric layer 412 of the interconnect layer 406 of the semiconductor device 202b may be directly bonded together with a dielectric layer 234 of the frontside interconnect layer 224 of the semiconductor device 202a by dielectric-to-dielectric bonds.

The bonding pads 420 of the semiconductor device 202a may be electrically coupled to the conductive structures 236 of the frontside interconnect layer 224 by bonding vias 422. The bonding pads 420 and bonding vias 422 may each include tungsten (W), cobalt (Co), ruthenium (Ru), titanium (Ti), aluminum (Al), copper (Cu), gold (Au), and/or a combination thereof, among other examples of electrically conductive metals.

As indicated above, FIGS. 4A and 4B are provided as an example. Other examples may differ from what is described with regard to FIGS. 4A and 4B.

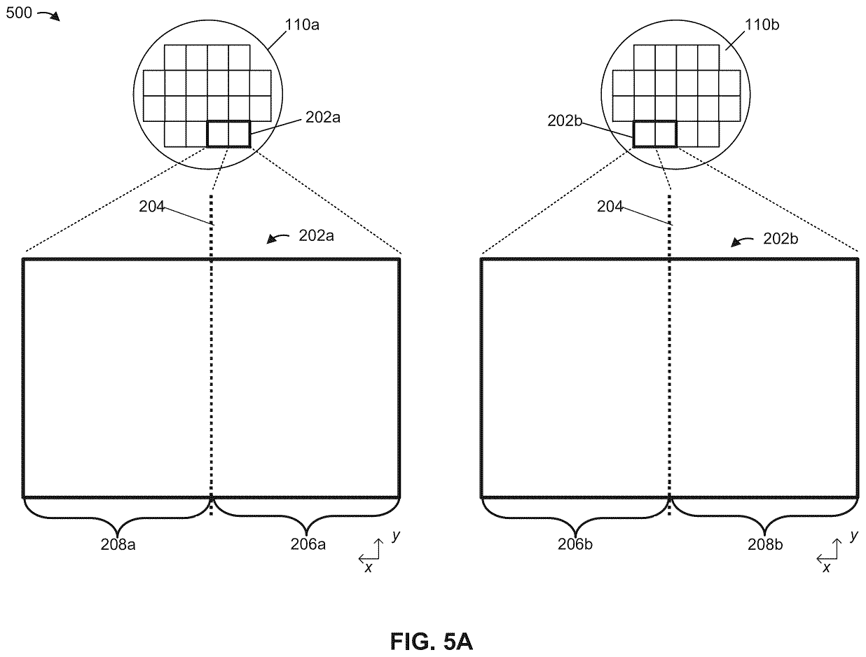

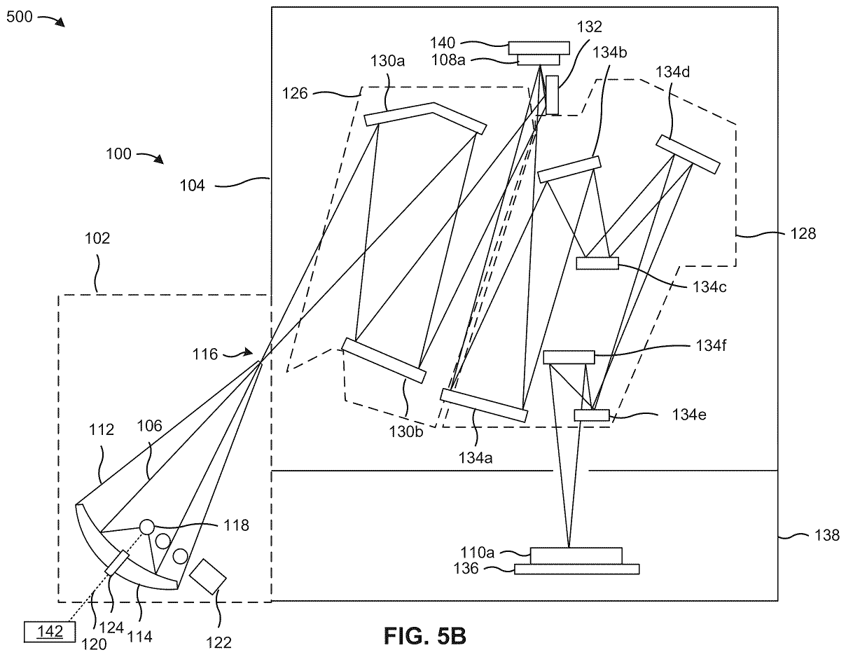

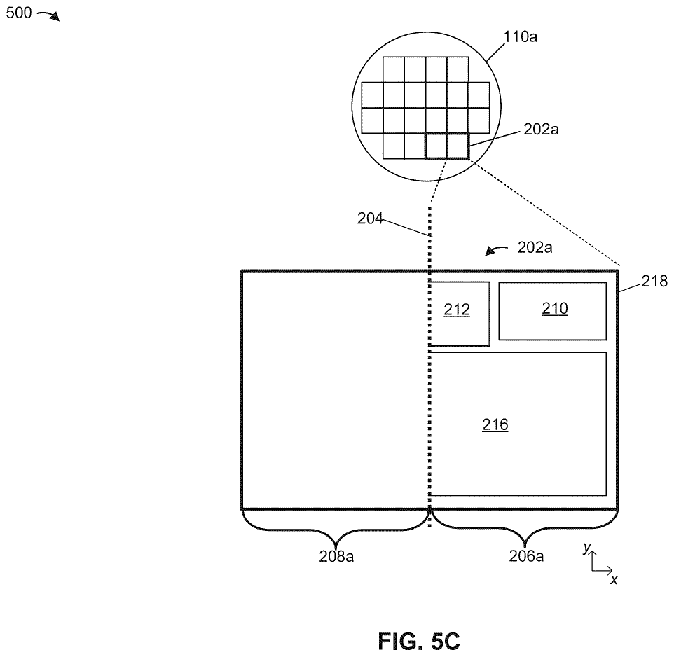

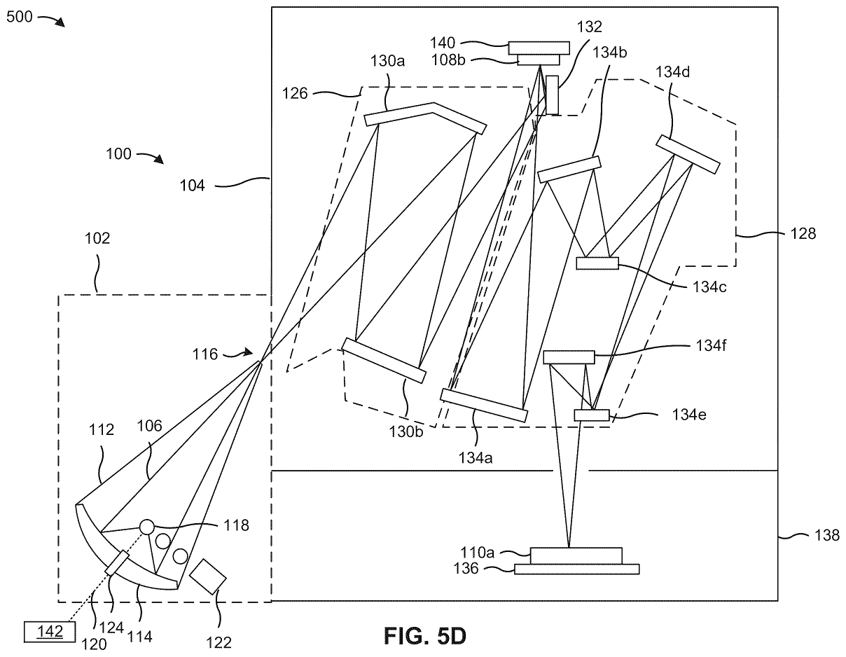

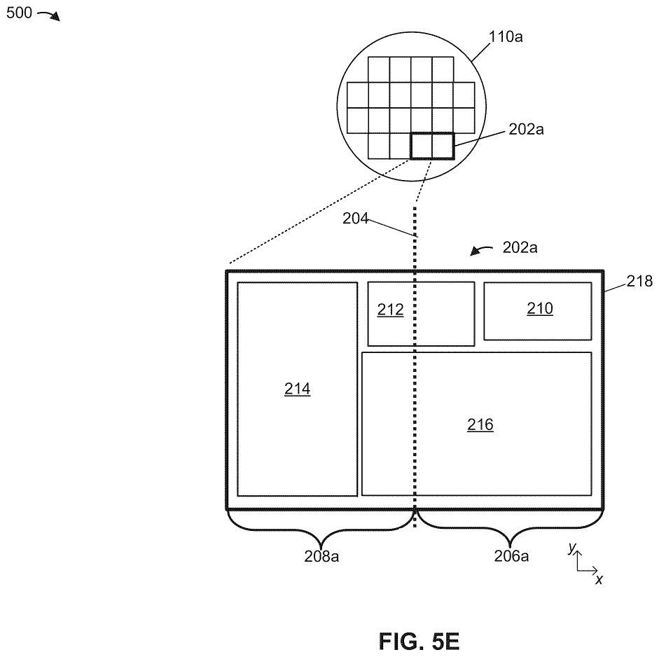

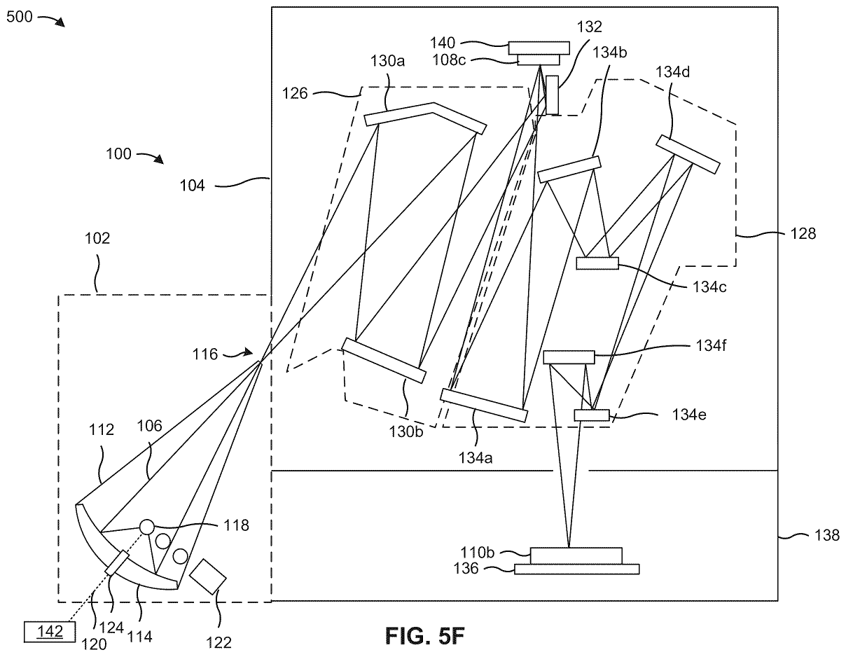

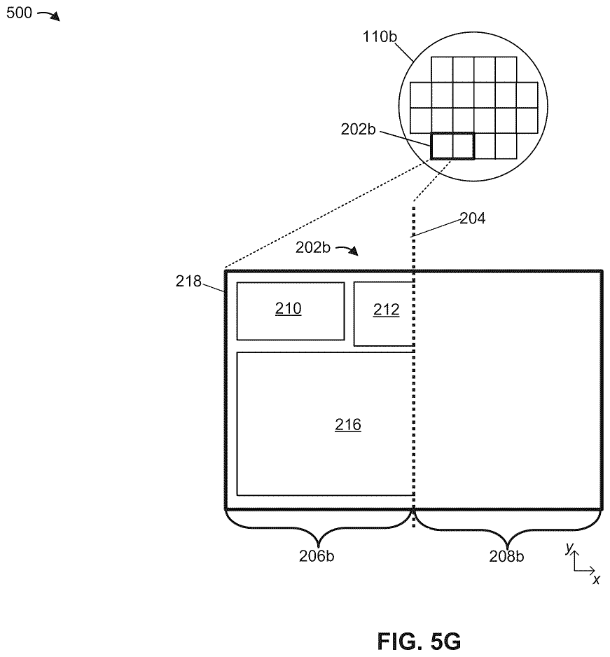

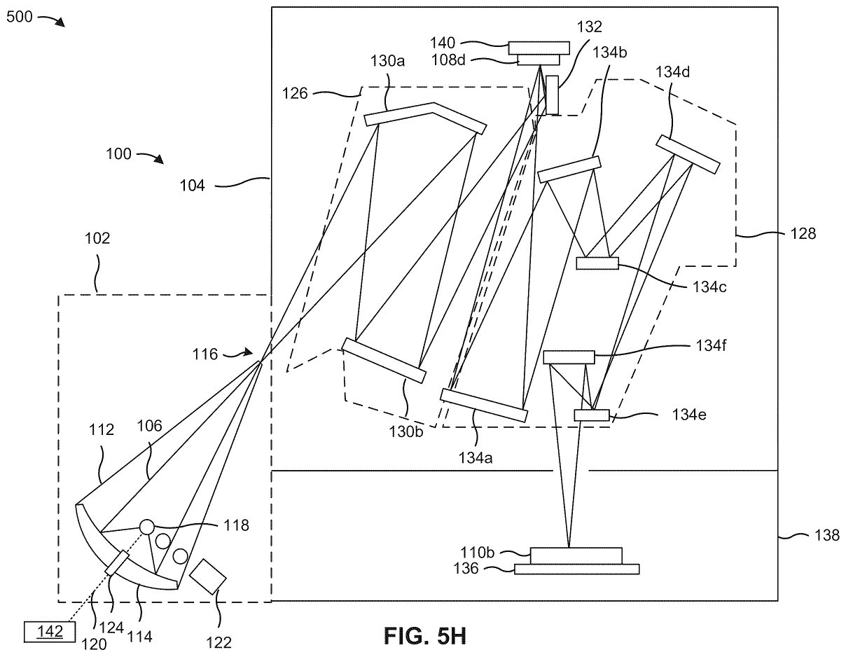

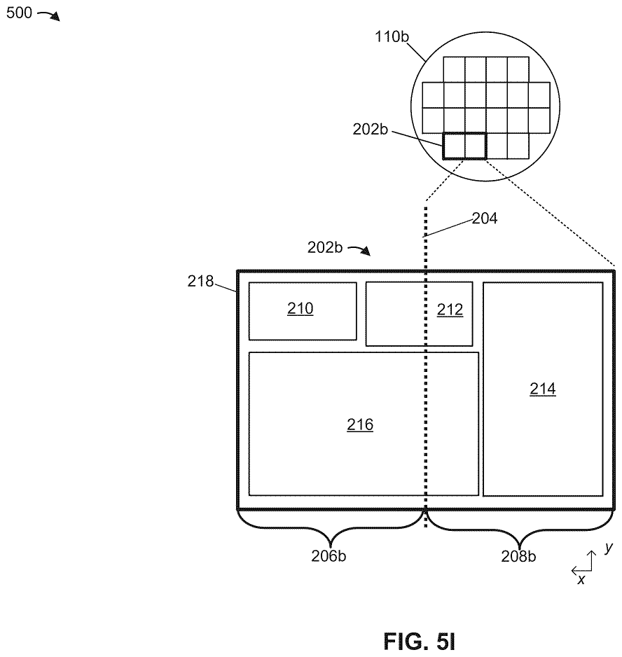

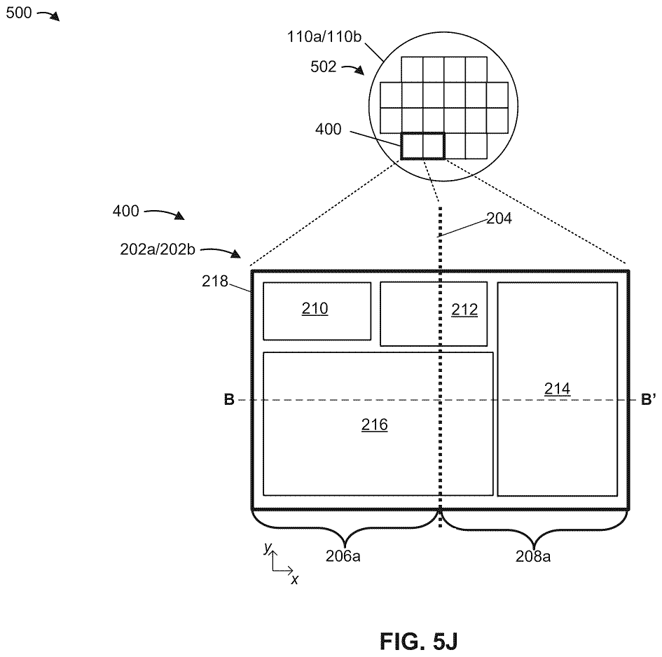

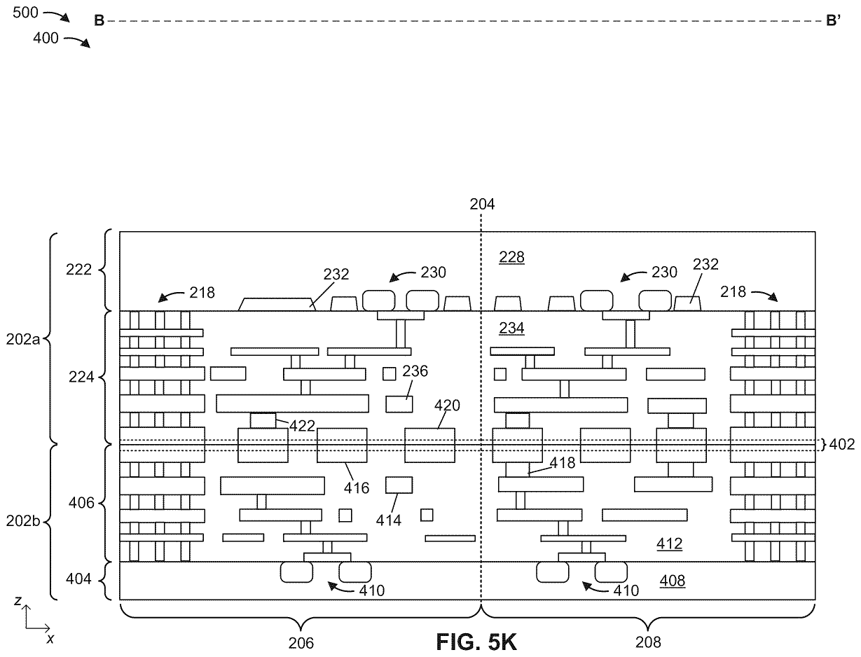

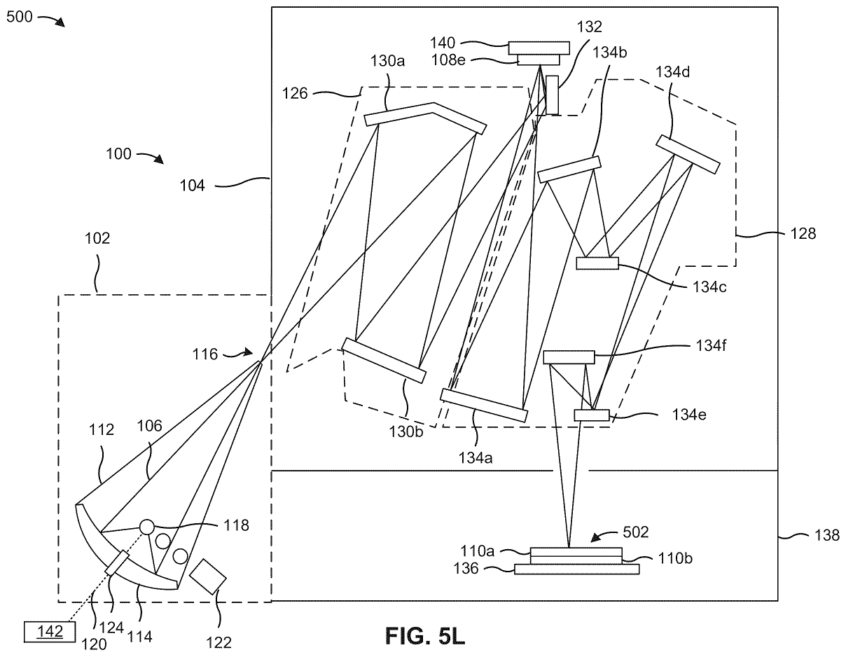

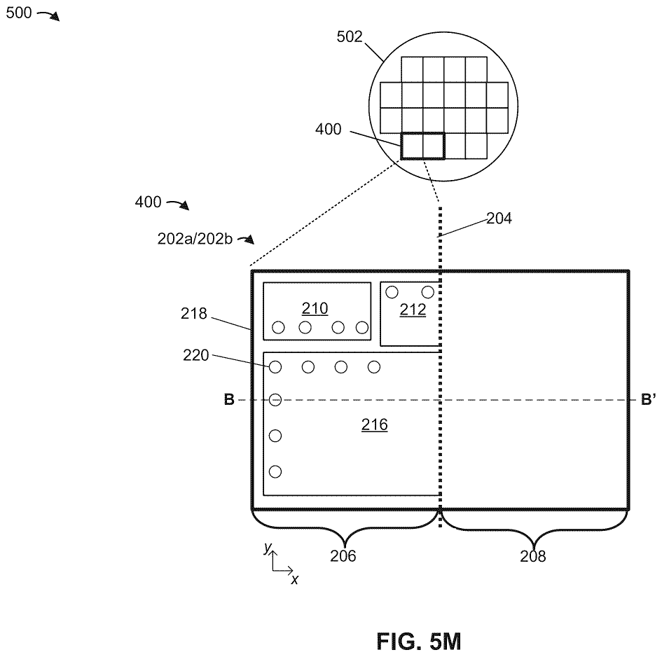

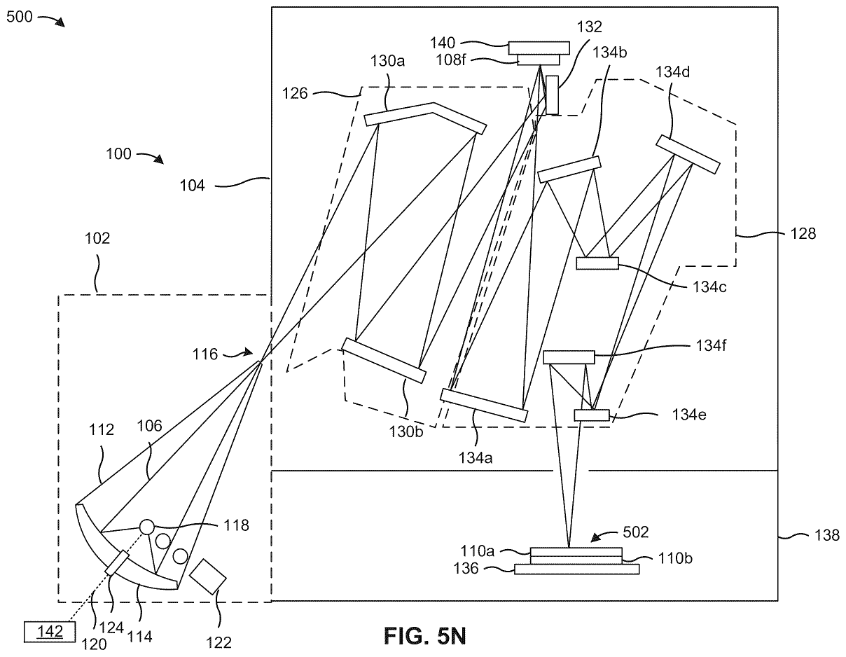

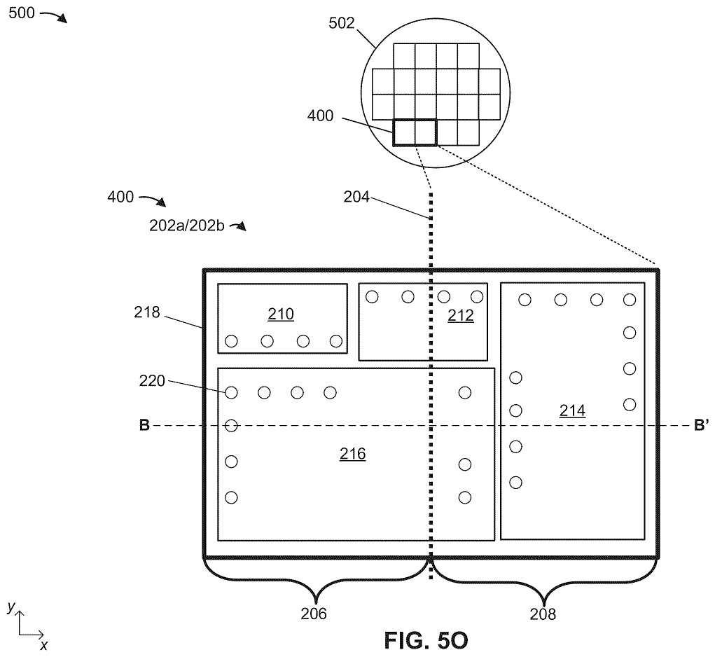

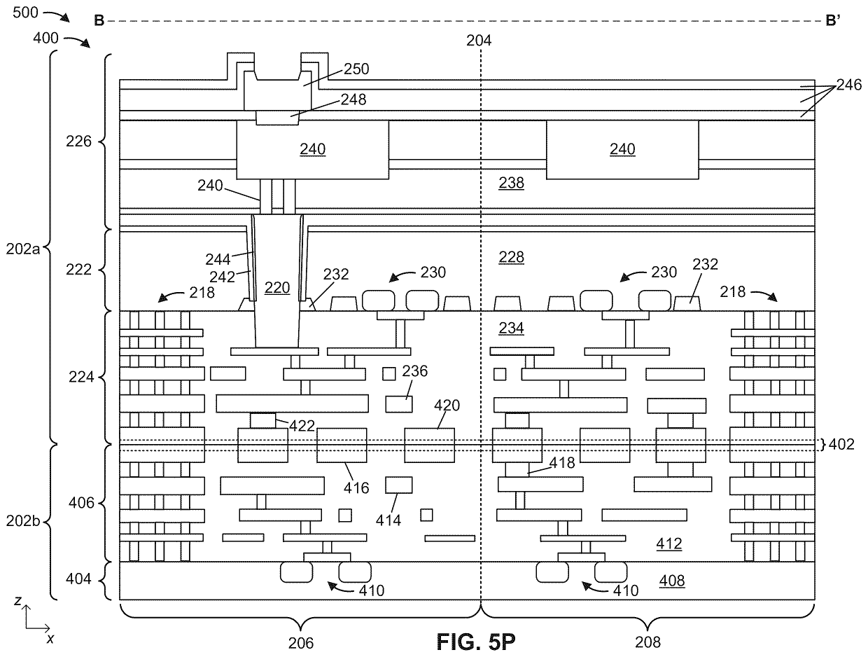

FIGS. 5A-5P are diagrams of an example implementation 500 of forming the stacked semiconductor device described herein. The example implementation 500 includes the use of similar multiple-reticle exposure techniques described in connection with FIGS. 3A-3W to form different layouts on the frontsides of the semiconductor devices 202a and 202b, as well as on the backside of the semiconductor device 202a, using different sets of reticles 108. In some implementations, one or more semiconductor processing tools, such as a deposition tool, an exposure tool (e.g., the lithography system 100), a developer tool, an etch tool, an ion implantation tool, a bonding tool, a planarization tool, and/or another type of semiconductor processing tool, may be used to perform one or more operations described in connection with FIGS. 5A-5P.

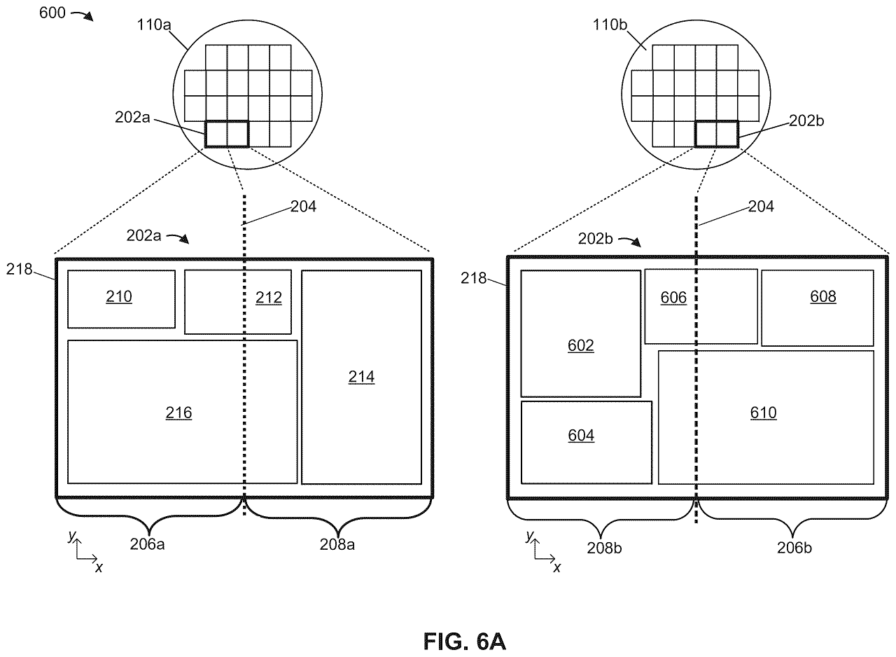

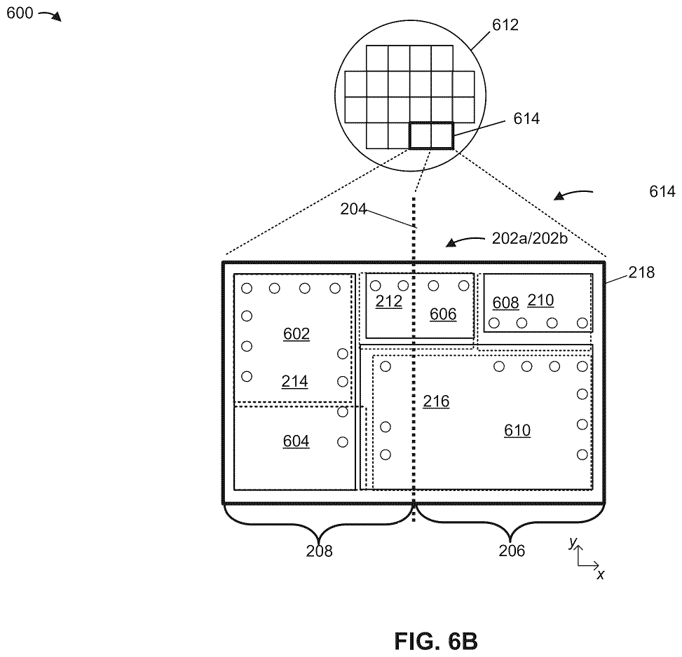

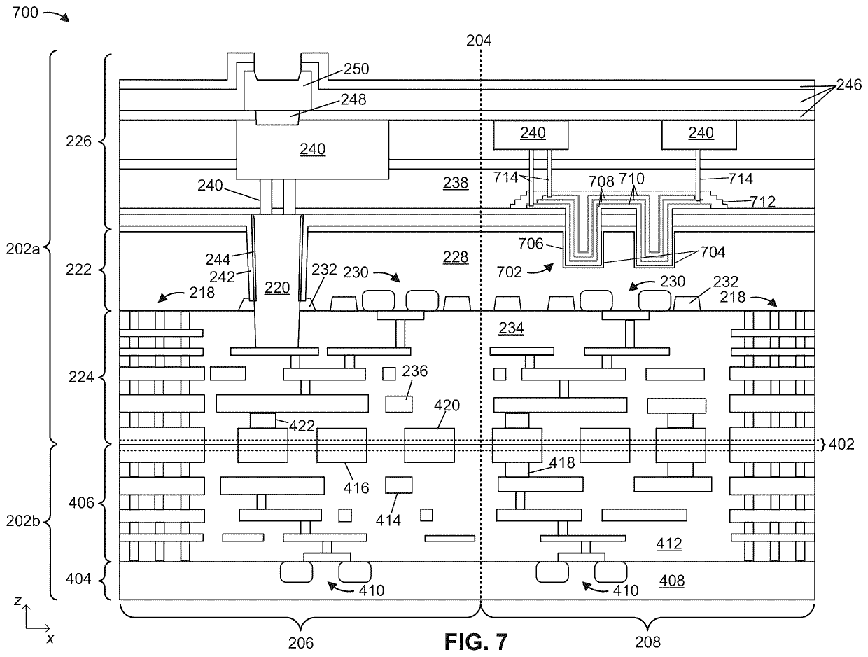

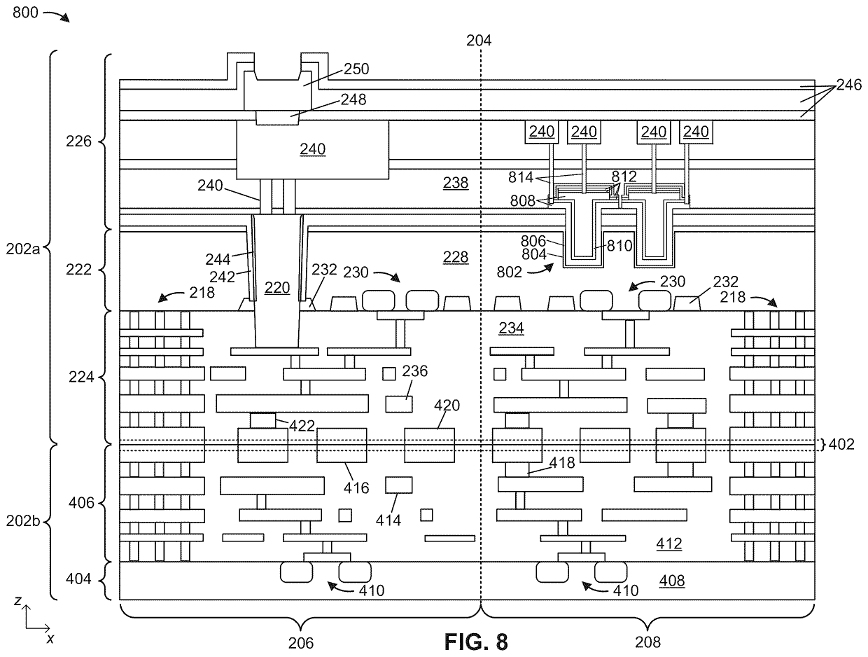

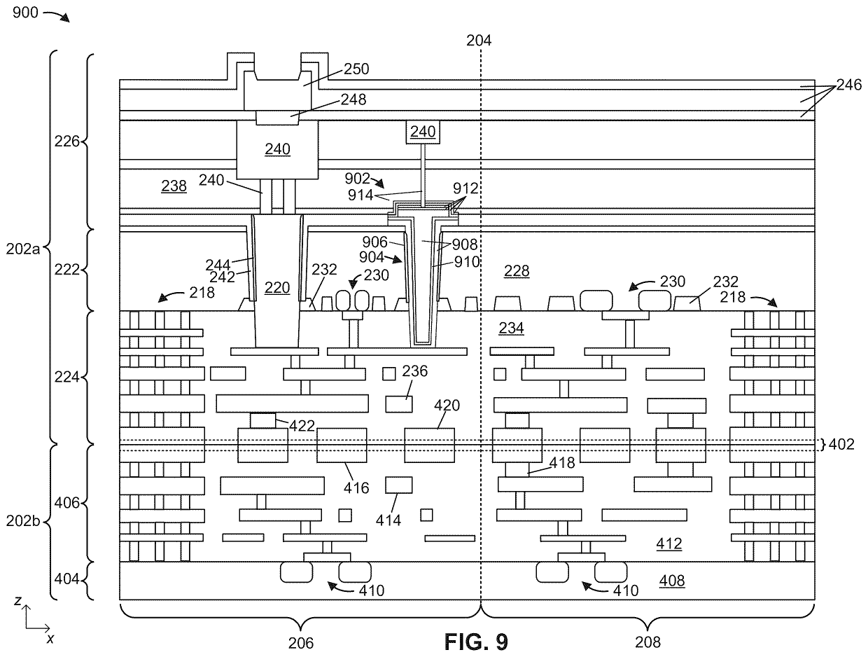

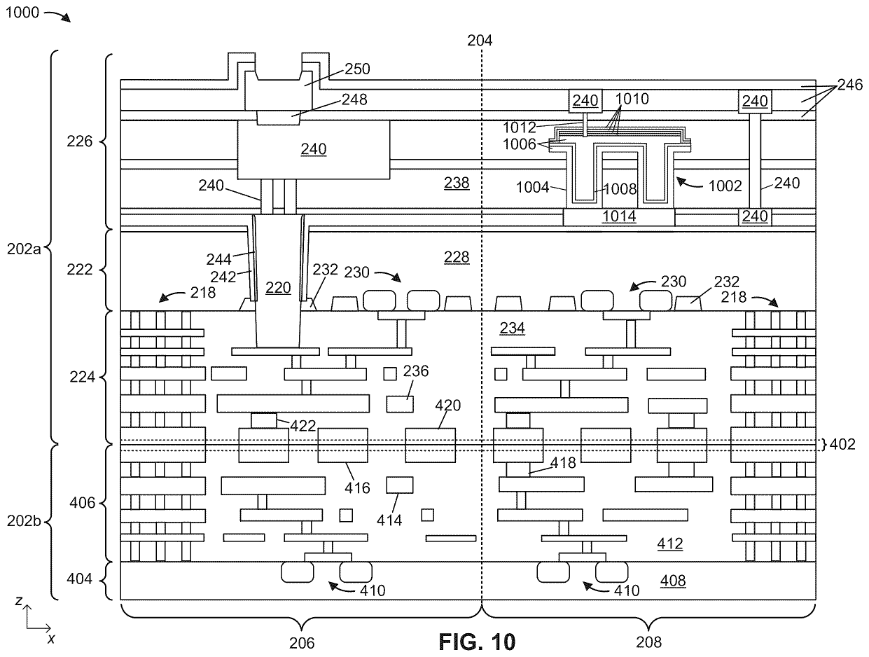

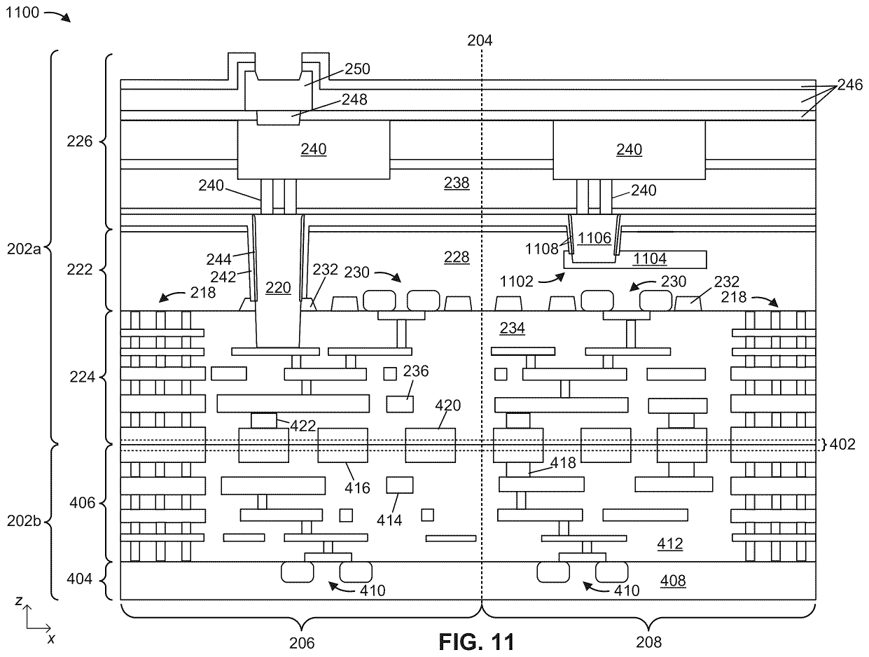

While the example implementation 500 is illustrated in FIGS. 5A-5P as being performed to form the stacked semiconductor device 400, the operations performed in connection with FIGS. 5A-5P may be performed to form another stacked semiconductor device described herein, such as a stacked semiconductor device 614 illustrated in FIG. 6B, a stacked semiconductor device 700 illustrated in FIG. 7, a stacked semiconductor device 800 illustrated in FIG. 8, a stacked semiconductor device 900 illustrated in FIG. 9, a stacked semiconductor device 1000 illustrated in FIG. 10, a stacked semiconductor device 1100 illustrated in FIG. 11, and/or another stacked semiconductor device.

As shown in FIG. 5A, the semiconductor devices 202a and 202b may be fabricated on different semiconductor wafers 110. For example, the semiconductor device 202a may be fabricated on a semiconductor wafer 110a, and the semiconductor device 202b may be fabricated on a semiconductor wafer 110b. This enables lateral regions 206 and 208 to be separately patterned using a multiple-reticle exposure technique for both of the semiconductor devices 202a and 202b. In particular, this enables lateral regions 206a and 208a to be separately patterned on the semiconductor device 202a using a multiple-reticle exposure technique, and enables lateral regions 206b and 208b to be separately patterned on the semiconductor device 202b using a multiple-reticle exposure technique.

As shown in FIGS. 5B-5I, multiple-reticle exposure techniques may be used to form patterns and/or structures on the frontsides of the semiconductor devices 202a and on the frontsides of the semiconductor devices 202b respectively formed on the semiconductor wafers 110a and 110b. The frontside processing for the semiconductor devices 202a and 202b may include a similar set of operations, including the use of the multiple-reticle exposure technique, as illustrated and described in connection with FIGS. 3N-3L.

For example, and as shown in FIGS. 5B and 5C, a set of reticles 108a may be used to pattern the lateral regions 206a of the semiconductor devices 202a on the semiconductor wafer 110a to form circuit layouts on the frontsides (e.g., the frontside regions) of the lateral regions 206a in and/or above the frontsides of the device layers 222 of the semiconductor devices 202a. This may include forming integrated circuit devices 230 in and/or on the frontsides of the device layers 222 in the lateral regions 206a, forming isolation regions 232 in and/or on the frontsides of the device layers 222, and/or forming layers of conductive structures 236 in the frontside interconnect layers 224 above the frontsides of the device layers 222 of the semiconductor devices 202a, among other examples. As shown in FIGS. 5D and 5E, a set of reticles 108 b may be used to pattern the lateral regions 208 a of the semiconductor devices 202a on the semiconductor wafer 110a to form circuit layouts on the frontsides (e.g., the frontside regions) of the lateral regions 208a in and/or above the frontsides of the device layers 222 of the semiconductor devices 202a. This may include forming integrated circuit devices 230 in and/or on the frontsides of the device layers 222 in the lateral regions 208a, forming isolation regions 232 in and/or on the frontsides of the device layers 222, and/or forming layers of conductive structures 236 in the frontside interconnect layers 224 above the frontsides of the device layers 222 of the semiconductor devices 202a, among other examples.

The uses of the sets of reticles 108a and 108b may be sequential. For example, the semiconductor wafer 110a may be placed on the wafer stage 136 of the lithography system 100, a first reticle 108a may be loaded into the reticle stage 140 of the lithography system 100, and the first reticle 108a may be used to perform a first exposure operation to pattern the frontsides of the device layers 222 in the lateral regions 206a to form an arrangement of integrated circuit devices 230 in the lateral regions 206a. The first reticle 108a may be removed from the reticle stage 140 and replaced with a first reticle 108b, and the first reticle 108b may be used to perform a second exposure operation (e.g., after the first exposure operation) to pattern the frontsides of the device layers 222 in the lateral regions 208a to form an arrangement of integrated circuit devices 230 in the lateral regions 208a.

As another example, a dielectric layer 234 of the frontside interconnect layer 224 may be deposited over the frontside of the device layer 222 of the semiconductor devices 202a. The semiconductor wafer 110a may be placed on the wafer stage 136 of the lithography system 100, a second reticle 108a may be loaded into the reticle stage 140 of the lithography system 100, and the second reticle 108a may be used to perform a third exposure operation (e.g., after the second exposure operation) to pattern the first dielectric layer 234 in the lateral regions 206a. The second reticle 108a may be removed from the reticle stage 140 and replaced with a second reticle 108b in the lithography system 100, and the second reticle 108b may be used to perform a fourth exposure operation (e.g., after the third exposure operation) to pattern the first dielectric layer 234 in the lateral regions 208a. A layer of metal material may be deposited in the respective patterns of the lateral regions 206a and 208a to form different arrangements in a first layer of conductive structures 236 in the lateral regions 206a and 208a. Subsequent reticles 108a and 108b may be used in a similar sequential manner for patterning additional layers of conductive structures 236.

As shown in FIGS. 5F and 5G, a set of reticles 108c may be used to pattern the lateral regions 206b of the semiconductor devices 202b on the semiconductor wafer 110b to form circuit layouts on the frontsides (e.g., the frontside regions) of the lateral regions 206b in and/or above the frontsides of the device layers 222 of the semiconductor devices 202b.

This may include forming integrated circuit devices 230 in and/or on the frontsides of the device layers 222 in the lateral regions 206b, forming isolation regions 232 in and/or on the frontsides of the device layers 222, and/or forming layers of conductive structures 236 in the frontside interconnect layers 224 above the frontsides of the device layers 222 of the semiconductor devices 202b, among other examples. As shown in FIGS. 5H and 5I, a set of reticles 108d may be used to pattern the lateral regions 208b of the semiconductor devices 202b on the semiconductor wafer 110b to form circuit layouts on the frontsides (e.g., the frontside regions) of the lateral regions 208b in and/or above the frontsides of the device layers 222 of the semiconductor devices 202b. This may include forming integrated circuit devices 230 in and/or on the frontsides of the device layers 222 in the lateral regions 208b, forming isolation regions 232 in and/or on the frontsides of the device layers 222, and/or forming layers of conductive structures 236 in the frontside interconnect layers 224 above the frontsides of the device layers 222 of the semiconductor devices 202b, among other examples.

The uses of the sets of reticles 108c and 108d may be sequential. For example, the semiconductor wafer 110b may be placed on the wafer stage 136 of the lithography system 100, a first reticle 108c may be loaded into the reticle stage 140 of the lithography system 100, and the first reticle 108c may be used to perform a first exposure operation to pattern the frontsides of the device layers 222 in the lateral regions 206b to form an arrangement of integrated circuit devices 230 in the lateral regions 206b. The first reticle 108c may be removed from the reticle stage 140 and replaced with a first reticle 108d, and the first reticle 108d may be used to perform a second exposure operation (e.g., after the first exposure operation) to pattern the frontsides of the device layers 222 in the lateral regions 208b to form an arrangement of integrated circuit devices 230 in the lateral regions 208b.

As another example, a dielectric layer 234 of the frontside interconnect layer 224 may be deposited over the frontside of the device layer 222 of the semiconductor devices 202b. The semiconductor wafer 110b may be placed on the wafer stage 136 of the lithography system 100, a second reticle 108c may be loaded into the reticle stage 140 of the lithography system 100, and the second reticle 108c may be used to perform a third exposure operation (e.g., after the second exposure operation) to pattern the first dielectric layer 234 in the lateral regions 206b. The second reticle 108c may be removed from the reticle stage 140 and replaced with a second reticle 108d of the lithography system 100, and the second reticle 108d may be used to perform a fourth exposure operation (e.g., after the third exposure operation) to pattern the first dielectric layer 234 in the lateral regions 208b. A layer of metal material may be deposited in the respective patterns of the lateral regions 206b and 208b to form different arrangements in a first layer of conductive structures 236 in the lateral regions 206b and 208b. Subsequent reticles 108c and 108d may be used in a similar sequential manner for patterning additional layers of conductive structures 236.

As shown in FIGS. 5J and 5K, the semiconductor devices 202a and 202b may be bonded together after frontside processing of the semiconductor devices 202a and 202b. The bond between the semiconductor devices 202a and 202b may be formed by bonding the semiconductor wafers 110a and 110b together (e.g., wafer-to-wafer bonding), by bonding dies together (die-to-die bonding), and/or by bonding a die to a wafer (e.g., die-to-wafer bonding), among other example bonding configurations.

As shown in FIG. 5J, bonding the semiconductor wafers 110a and 110b together forms a wafer stack 502 that includes the bonded semiconductor wafers 110a and 110b. The wafer stack 502 includes a plurality of stacked semiconductor devices 400 that are formed by bonding the semiconductor devices 202a of the semiconductor wafer 110a with the semiconductor devices 202b of the semiconductor wafer 110b.

As shown in FIG. 5K, a bonding tool may be used to perform a bonding operation to bond the semiconductor devices 202a and 202b by forming metal-to-metal bonds between the bonding pads 416 of the semiconductor device 202b and the bonding pads 420 of the semiconductor device 202a, and/or dielectric-to-dielectric bonds between the dielectric layer(s) 234 of the semiconductor device 202a and the dielectric layer(s) 412 of the semiconductor device 202b.

As further shown in FIG. 5K, bonding the semiconductor devices 202a and 202b in the stacked arrangement joins together the lateral regions 206a and 206b, respectively, of the semiconductor devices 202a and 202b, as well as joins together the lateral regions 208a and 208b, respectively, of the semiconductor devices 202a and 202b. Thus, the integrated circuits of the functional regions 210, 212, and 216 may include a combination of electrically connected integrated circuit devices 230 and 410, respectively, of the semiconductor devices 202a and 202b in the lateral region 206 of the stacked semiconductor device 400 (which includes the lateral regions 206a and 206b). The integrated circuits of the functional regions 212, 214, and 216 may include a combination of electrically connected integrated circuit devices 230 and 410, respectively, of the semiconductor devices 202a and 202b in the lateral region 208 of the stacked semiconductor device 400 (which includes the lateral regions 208a and 208b).

As shown in FIGS. 5L-5P, backside processing may be performed for the semiconductor device 202a. The backside processing for the semiconductor device 202a may include a similar set of operations, including the use of the multiple-reticle exposure technique, as illustrated and described in connection with FIGS. 3N-3W. For example, and as shown in FIGS. 5L and 5M, a set of reticles 108e may be used to pattern the lateral region 206 of the stacked semiconductor device 400 to form a circuit layout from the backside of the device layer 222 to the frontside interconnect layer 224 as well as to form a circuit layout in the backside interconnect layer 226 (e.g., the backside region) of the lateral region 206 above the backside of the semiconductor device 202a. As shown in FIGS. 5N and 5O, a different set of reticles 108f may be used to pattern the lateral region 208 of the stacked semiconductor device 400 to form a circuit layout from the backside of the device layer 222 to the frontside interconnect layer 224 as well as to form a circuit layout in the backside interconnect layer 226 (e.g., the backside region) of the lateral region 208 above the backside of the semiconductor device 202a.

The uses of the sets of reticles 108e and 108f may be sequential. For example, a dielectric layer 238 of the backside interconnect layer 226 may be deposited over the backside of the device layer 222 of the semiconductor device 202a. The stacked semiconductor device 400 may be placed on the wafer stage 136 of the lithography system 100, a first reticle 108e may be loaded into the reticle stage 140 of the lithography system 100, and the first reticle 108e may be used to perform a first exposure operation to pattern the first dielectric layer 238 in the lateral region 206. The first reticle 108e may be removed from the reticle stage 140 and replaced with a first reticle 108f of the lithography system 100, and the first reticle 108f may be used to perform a second exposure operation to pattern the first dielectric layer 238 in the lateral region 208. A layer of metal material may be deposited in the respective patterns of the lateral regions 206 and 208 to form different arrangements in a first layer of conductive structures 240 in the lateral regions 206 and 208. Subsequent reticles 108e and 108f may be used in a similar sequential manner for patterning additional layers of conductive structures 240.

The above-described sequential process may be performed at the wafer level for a plurality of stacked semiconductor devices 400 formed from the wafer stack 502. For example, and as shown in FIGS. 5L and 5M, the set of reticles 108e may be used to pattern the lateral regions 206 of the stacked semiconductor devices 400 of the wafer stack 502 to form circuit layouts in the backside interconnect layers 226 (e.g., the backside regions) of the lateral regions 206 of the stacked semiconductor devices 400. As shown in FIGS. 5N and 5O, a different set of reticles 108f may be used to pattern the lateral regions 208 of the stacked semiconductor devices 400 of the wafer stack 502 to form a circuit layout in the backside interconnect layers 226 (e.g., the backside regions) of the lateral regions 208 of the stacked semiconductor devices 400.

As shown in FIG. 5P, the backside processing may be performed to form one or more through-substrate interconnect structures 220 (and the associated liners 242, 244) through the substrate layer 228 of the semiconductor device 202a, to form the dielectric layer(s) 238 of the backside interconnect layer 226, to form the conductive structures 240 of the backside interconnect layer 226, to form the passivation layers 246, and/or to form the connection pads 248 and the connection structures 250, among other examples.

After the semiconductor devices 202a and 202b are bonded together to form the stacked semiconductor device 400, a die singulation tool may be used to dice or cut the stacked semiconductor devices 400 from the semiconductor wafers 110a and 110b so that the stacked semiconductor devices 400 can be packaged and/or shipped to another facility for further processing.

As indicated above, FIGS. 5A-5P are provided as an example. Other examples may differ from what is described with regard to FIGS. 5A-5P.

FIGS. 6A and 6B are diagrams of an example implementation 600 of forming the stacked semiconductor device described herein. The example implementation 600 includes the use of similar multiple-reticle exposure techniques described in connection with FIGS. 3A-3W and/or 5A-5P to form different layouts on the frontsides of the semiconductor devices 202a and 202b, as well as on the backside of the semiconductor device 202a, using different sets of reticles 108.

The example implementation 600 is similar to the example implementation 500 of forming the stacked semiconductor device 400. However, as illustrated in FIG. 6A, the semiconductor devices 202a and 202b are fabricated such that the semiconductor devices 202a and 202b include asymmetric circuit layouts in the example implementation 600, as opposed to mirrored circuit layouts in the stacked semiconductor device 400. The semiconductor device 202a may be manufactured (e.g., using similar multiple-reticle exposure techniques described in connection with FIGS. 3A-3W and/or 5A-5P) to include the functional regions 210-216, whereas the semiconductor device 202b may be manufactured (e.g., using similar multiple-reticle exposure techniques described in connection with FIGS. 3A-3W and/or 5A-5P) to include the functional regions 602-610. Thus, the lateral region 206a of the semiconductor device 202a and the lateral region 206b of the semiconductor device 202b may have different circuit layouts for different functional region arrangements, and/or the lateral region 208a of the semiconductor device 202a and the lateral region 208b of the semiconductor device 202b may have different circuit layouts for different functional region arrangements.

As shown in FIG. 6B, the semiconductor wafers 110a and 110b on which the semiconductor devices 202a and 202b are respectively formed may be bonded together to form a wafer stack 612 that includes a plurality of stacked semiconductor devices 614. Each stacked semiconductor device 614 may include a stacked arrangement of a semiconductor device 202a and a semiconductor device 202b. The lateral regions 206a and 206b are stacked together to form a lateral region 206 of the stacked semiconductor devices 614, and the lateral regions 208a and 208b are stacked together to form a lateral region 208 of the stacked semiconductor devices 614. In some implementations, backside processing (e.g., using similar multiple-reticle exposure techniques described in connection with FIGS. 3A-3W and/or 5A-5P) may be performed on the wafer stack 612 to form backside circuit layouts in the lateral regions 206 and/or 208 of the stacked semiconductor devices 614.

As indicated above, FIGS. 6A and 6B are provided as an example. Other examples may differ from what is described with regard to FIGS. 6A and 6B.

FIG. 7 is a diagram of an example stacked semiconductor device 700 described herein. FIG. 7 illustrates a cross-section view of the stacked semiconductor device 700. The stacked semiconductor device 700 may include a similar top view layout as the stacked semiconductor device 400 and/or 614, and may be formed using multiple-reticle exposure techniques described in connection with FIGS. 3A-3W and/or 5A-5P to form different layouts on the frontsides of the semiconductor devices 202a and 202b, as well as on the backside of the semiconductor device 202a, using different sets of reticles 108.

However, as illustrated in FIG. 7, the multiple-reticle exposure techniques described in connection with FIGS. 3A-3W and/or 5A-5P may be used to form one or more capacitor structures 702 in the lateral region 206 and/or the lateral region 208 of the stacked semiconductor device 700. The capacitor structure 702 may be a trench capacitor structure that includes one or more trenches 704 that extend into the backside of the device layer 222 (e.g., that extend into the substrate layer 228 from the backside of the substrate layer 228).

A barrier layer 706 may be included on the sidewalls and on the bottom surfaces of the trenches 704. The barrier layer 706 may include a conformal dielectric layer that includes one or more dielectric materials. In some implementations, the barrier layer 706 includes a high-k dielectric material such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAIO₃), among other examples. In some implementations, the barrier layer 706 includes a low-k dielectric material such as a silicon oxide (SiOₓ), an undoped silicate glass (USG), a boron-containing silicate glass (BSG), and/or a fluorine-containing silicate glass (FSG), among other examples.

The capacitor structure 702 may further include a plurality of conformal layers that extend into and between the trenches 704. For example, the capacitor structure 702 may include an alternating arrangement of electrode layers 708 and insulator layers 710. The alternating arrangement of electrode layers 708 and insulator layers 710 may enable electrical charge to be stored in the electrode layers 708 based on capacitance provided by the electrical separation of the insulator layers 710.

The electrode layers 708 may include one or more metals such as titanium (Ti), tantalum (Ta), ruthenium (Ru), aluminum (Al), copper (Cu), cobalt (Co), and/or platinum (Pt), among other examples. Additionally and/or alternatively, the electrode layers 708 may include one or more metal alloys such as titanium nitride (TiN) and/or tantalum nitride (TaN), among other examples.

In some implementations, the insulator layers 710 include a high-k dielectric material such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAIO₃), among other examples. In some implementations, the insulator layers 710 include a low-k dielectric material such as a silicon oxide (SiOₓ), an undoped silicate glass (USG), a boron-containing silicate glass (BSG), and/or a fluorine-containing silicate glass (FSG), among other examples.

In some implementations, a capping layer 712 may fill in the remaining areas of the trenches 704 and may function as a patterning layer for forming contacts 714 of the capacitor structure 702. The capping layer 712 may also provide electrical isolation between adjacent contacts 714. The contacts 714 may include vias, interconnects, pillars, plugs, and/or another type of electrically conductive structures. The contacts 714 may be electrically coupled and/or physically coupled to one or more conductive structures 240 in the backside interconnect layer 226.

As indicated above, FIG. 7 is provided as an example. Other examples may differ from what is described with regard to FIG. 7.

FIG. 8 is a diagram of an example stacked semiconductor device 800 described herein. FIG. 8 illustrates a cross-section view of the stacked semiconductor device 800. The stacked semiconductor device 800 may include a similar top view layout as the stacked semiconductor device 400 and/or 614, and may be formed using multiple-reticle exposure techniques described in connection with FIGS. 3A-3W and/or 5A-5P to form different layouts on the frontsides of the semiconductor devices 202a and 202b, as well as on the backside of the semiconductor device 202a, using different sets of reticles 108.

However, as illustrated in FIG. 8, the multiple-reticle exposure techniques described in connection with FIGS. 3A-3W and/or 5A-5P may be used to form one or more capacitor structures 802 in the lateral region 206 and/or the lateral region 208 of the stacked semiconductor device 800. Each capacitor structure 802 may be a trench capacitor structure that includes a trench 804 that extends into the backside of the device layer 222 (e.g., that extends into the substrate layer 228 from the backside of the substrate layer 228).

A barrier layer 806 may be included on the sidewalls and on the bottom surfaces of a trench 804 of a capacitor structure 802. The barrier layer 806 may include a conformal dielectric layer that includes one or more dielectric materials. In some implementations, the barrier layer 806 includes a high-k dielectric material such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAIO₃), among other examples. In some implementations, the barrier layer 806 includes a low-k dielectric material such as a silicon oxide (SiOₓ), an undoped silicate glass (USG), a boron-containing silicate glass (BSG), and/or a fluorine-containing silicate glass (FSG), among other examples.

Each capacitor structure 802 may further include a plurality of electrode layers 808 and an insulator layer 810 sandwiched between the electrode layers 808. The electrode layers 808 may include a conformal bottom electrode layer that conforms to the sidewalls and bottom surface of the associated trench 804, and a top electrode layer that fills in the remaining area of the trench 804.

The electrode layers 808 may include one or more metals such as titanium (Ti), tantalum (Ta), ruthenium (Ru), aluminum (Al), copper (Cu), cobalt (Co), and/or platinum (Pt), among other examples. Additionally and/or alternatively, the electrode layers 808 may include one or more metal alloys such as titanium nitride (TiN) and/or tantalum nitride (TaN), among other examples.

In some implementations, the insulator layers 810 include a high-k dielectric material such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAIO₃), among other examples. In some implementations, the insulator layers 810 include a low-k dielectric material such as a silicon oxide (SiOₓ), an undoped silicate glass (USG), a boron-containing silicate glass (BSG), and/or a fluorine-containing silicate glass (FSG), among other examples.

In some implementations, a capacitor structure 802 includes a plurality of capping layers 812 over the top electrode layer and/or over portions of the insulator layer 810 that extend laterally outward from the associated trench 804. The capping layers 812 may be used to etch the electrode layers 808 and the insulator layers 810 of the capacitor structures 802 to electrically isolate the capacitor structures 802. The capping layers 812 may also be used to form contacts 814 of the capacitor structures 802. The capping layer 812 may also provide electrical isolation between adjacent contacts 814. The contacts 814 may include vias, interconnects, pillars, plugs, and/or another type of electrically conductive structures. The contacts 814 may be electrically coupled and/or physically coupled to one or more conductive structures 240 in the backside interconnect layer 226.

As indicated above, FIG. 8 is provided as an example. Other examples may differ from what is described with regard to FIG. 8.

FIG. 9 is a diagram of an example stacked semiconductor device 900 described herein. FIG. 9 illustrates a cross-section view of the stacked semiconductor device 900. The stacked semiconductor device 900 may include a similar top view layout as the stacked semiconductor device 400 and/or 614, and may be formed using multiple-reticle exposure techniques described in connection with FIGS. 3A-3W and/or 5A-5P to form different layouts on the frontsides of the semiconductor devices 202a and 202b, as well as on the backside of the semiconductor device 202a, using different sets of reticles 108.

However, as illustrated in FIG. 9, the multiple-reticle exposure techniques described in connection with FIGS. 3A-3W and/or 5A-5P may be used to form one or more through-substrate capacitor structures 902 in the lateral region 206 and/or the lateral region 208 of the stacked semiconductor device 900. A through-substrate capacitor structure 902 may extend through the substrate layer 228 of the device layer 222 of the semiconductor device 202a from the backside of the device layer 222 to the frontside of the device layer 222. A first end of the through-substrate capacitor structure 902 may be electrically coupled and/or physically coupled to a conductive structure 236 in the frontside interconnect layer 224, and second end of the through-substrate capacitor structure 902 vertically opposing the first end may be electrically coupled and/or physically coupled to a conductive structure 240 in the backside interconnect layer 226. The through-substrate capacitor structure 902 may extend through an isolation region 232 in the substrate layer 228.

A through-substrate capacitor structure 902 may be a trench capacitor structure that includes a trench 904. A barrier layer 906 may be included on the sidewalls of the trench 904. The combination of the barrier layer 906 and the isolation region 232 may protect the through-substrate capacitor structure 902 from material migration into the substrate layer 228 and may provide electrical isolation between the through-substrate capacitor structure 902 and the integrated circuit devices 230 in the device layer 222. The barrier layer 906 may include a conformal dielectric layer that includes one or more dielectric materials. In some implementations, the barrier layer 906 includes a high-k dielectric material such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAIO₃), among other examples. In some implementations, the barrier layer 906 includes a low-k dielectric material such as a silicon oxide (SiOₓ), an undoped silicate glass (USG), a boron-containing silicate glass (BSG), and/or a fluorine-containing silicate glass (FSG), among other examples.

The through-substrate capacitor structure 902 may further include a plurality of electrode layers 908 and an insulator layer 910 sandwiched between the electrode layers 908. The electrode layers 908 may include a conformal bottom electrode layer that conforms to the sidewalls and bottom surface of the associated trench 904, and a top electrode layer that fills in the remaining area of the trench 904.

The electrode layer 908 may each include one or more metals such as titanium (Ti), tantalum (Ta), ruthenium (Ru), aluminum (Al), copper (Cu), cobalt (Co), and/or platinum (Pt), among other examples. Additionally and/or alternatively, the electrode layers 908 may each include one or more metal alloys such as titanium nitride (TiN) and/or tantalum nitride (TaN), among other examples.

In some implementations, the insulator layer 910 includes a high-k dielectric material such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAIO₃), among other examples. In some implementations, the insulator layer 910 includes a low-k dielectric material such as a silicon oxide (SiOₓ), an undoped silicate glass (USG), a boron-containing silicate glass (BSG), and/or a fluorine-containing silicate glass (FSG), among other examples.

In some implementations, the through-substrate capacitor structure 902 includes a plurality of capping layers 912 over the top electrode layer and/or over portions of the insulator layer 910 that extend laterally outward from the trench 904. The capping layers 912 may be used to etch the electrode layers 908 and the insulator layer 910 of the through-substrate capacitor structure 902. The capping layers 912 may also be used to form contacts 914 of the through-substrate capacitor structure 902. The contacts 914 may include vias, interconnects, pillars, plugs, and/or another type of electrically conductive structures. The contacts 914 may be electrically coupled and/or physically coupled to one or more conductive structures 240 in the backside interconnect layer 226. In some implementations, the top electrode layer 908 may be electrically coupled and/or physically coupled to one or more conductive structures 240 in the backside interconnect layer 226 by contacts 914, and the bottom electrode layer 908 may be electrically coupled and/or physically coupled to another conductive structure 240 in the backside interconnect layer 226 through from conductive structure 236 in the frontside interconnect layer 224 to through-substrate interconnect structures 220, as shown in FIG. 9.

As indicated above, FIG. 9 is provided as an example. Other examples may differ from what is described with regard to FIG. 9.

FIG. 10 is a diagram of an example stacked semiconductor device 1000 described herein. FIG. 10 illustrates a cross-section view of the stacked semiconductor device 1000.

The stacked semiconductor device 1000 may include a similar top view layout as the stacked semiconductor device 400 and/or 614, and may be formed using multiple-reticle exposure techniques described in connection with FIGS. 3A-3W and/or 5A-5P to form different layouts on the frontsides of the semiconductor devices 202a and 202b, as well as on the backside of the semiconductor device 202a, using different sets of reticles 108.

However, as illustrated in FIG. 10, the multiple-reticle exposure techniques described in connection with FIGS. 3A-3W and/or 5A-5P may be used to form one or more capacitor structures 1002 in the lateral region 206 and/or the lateral region 208 of the stacked semiconductor device 1000. A capacitor structure 1002 may be a backend trench capacitor structure that is included in the dielectric layer(s) 238 of the backside interconnect layer 226 of the semiconductor device 202a.

As shown in FIG. 10, a capacitor structure 1002 may include one or more trenches 1004 that extend into and/or through one or more of the dielectric layers 238 of the backside interconnect layer 226 of the semiconductor device 202a. The capacitor structure 1002 may further include a plurality of electrode layers 1006 and an insulator layer 1008 sandwiched between the electrode layers 1006. The electrode layers 1006 may include a conformal bottom electrode layer that conforms to the sidewalls and bottom surface of the trenches 1004, and a top electrode layer that fills in the remaining area of the trenches 1004. The electrode layers 1006 and the insulator layer 1008 may continuously extend through and between the trenches 1004.

The electrode layers 1006 may include one or more metals such as titanium (Ti), tantalum (Ta), ruthenium (Ru), aluminum (Al), copper (Cu), cobalt (Co), and/or platinum (Pt), among other examples. Additionally and/or alternatively, the electrode layers 1006 may include one or more metal alloys such as titanium nitride (TiN) and/or tantalum nitride (TaN), among other examples.

In some implementations, the insulator layer 1008 may include a high-k dielectric material such as silicon nitride (SiₓN_{y} such as Si₃N₄), an aluminum oxide (AlₓO_{y} such as Al₂O₃), a tantalum oxide (TaₓO_{y} such as Ta2Os), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAIO₃), among other examples. In some implementations, the insulator layer 1008 may include a low-k dielectric material such as a silicon oxide (SiOₓ), an undoped silicate glass (USG), a boron-containing silicate glass (BSG), and/or a fluorine-containing silicate glass (FSG), among other examples.

In some implementations, a capacitor structure 1002 includes a plurality of capping layers 1010 over the top electrode layer and/or over portions of the insulator layer 1008 that extend laterally outward from the associated trenches 1004. The capping layers 1010 may be used to etch the electrode layers 1006 and the insulator layers 1008 of the capacitor structure 1002.

The capping layers 1010 may also be used to form top contacts 1012 of the capacitor structure 1002. The top contacts 1012 may include vias, interconnects, pillars, plugs, and/or another type of electrically conductive structures. The top contacts 1012 may be electrically coupled and/or physically coupled to one or more conductive structures 240 in the backside interconnect layer 226.

An electrode layer 1006 (e.g., a bottom electrode layer) may be electrically coupled and/or physically coupled to a bottom contact 1014 in the dielectric layer(s) 238 of the backside interconnect layer 226. Thus, the capacitor structure 1002 may include a top connection (e.g., to a top contact 1012) and a bottom connection (e.g., to a bottom contact 1014) to the backside interconnect layer 226.

As indicated above, FIG. 10 is provided as an example. Other examples may differ from what is described with regard to FIG. 10.

FIG. 11 is a diagram of an example stacked semiconductor device 1100 described herein. FIG. 11 illustrates a cross-section view of the stacked semiconductor device 1100.

The stacked semiconductor device 1100 may include a similar top view layout as the stacked semiconductor device 400 and/or 614, and may be formed using multiple-reticle exposure techniques described in connection with FIGS. 3A-3W and/or 5A-5P to form different layouts on the frontsides of the semiconductor devices 202a and 202b, as well as on the backside of the semiconductor device 202a, using different sets of reticles 108.

However, as illustrated in FIG. 11, the multiple-reticle exposure techniques described in connection with FIGS. 3A-3W and/or 5A-5P may be used to form one or more diode structures 1102 in the lateral region 206 and/or the lateral region 208 of the stacked semiconductor device 1100. A diode structure 1102 may extend into the backside of the device layer 222 (e.g., extend into the substrate layer 228 from the backside of the substrate layer 228).

As shown in FIG. 11, a diode structure 1102 may include a well region 1104 in the substrate layer 228 of the semiconductor device 202a. The well region 1104 may include a region of the substrate layer 228 that is doped with one or more types of dopants, such as n-type dopants (e.g., phosphorous (P), arsenic (As)) and/or p-type dopants (e.g., boron (B)).

The well region 1104 may be doped by ion implantation, diffusion, and/or another doping technique. The well region 1104 may include a p-n junction, which is a junction between a p-doped region and an n-doped region of the well region 1104.

As further shown in FIG. 11, the diode structure 1102 may include a contact 1106 that extends into the substrate layer 228 from the backside of the device layer 222 of the semiconductor device 202a. The contact 1106 may be formed of copper (Cu), gold (Au), silver (Ag), nickel (Ni), tin (Sn), ruthenium (Ru), cobalt (Co), tungsten (W), titanium (Ti), aluminum copper (AlCu), one or more other metals, one or more conductive ceramics, alloys thereof, and/or another type of electrically conductive material. The contact 1106 may be electrically coupled and/or physically coupled to one or more conductive structures 240 in the backside interconnect layer 226.

One or more barrier layers 1108 may be included on sidewalls of the contact 1106. The barrier layer(s) 1108 may include a conformal dielectric layer that includes one or more dielectric materials. In some implementations, a barrier layer 1108 includes a high-k dielectric material such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAIO₃), among other examples. In some implementations, a barrier layer 1108 includes a low-k dielectric material such as a silicon oxide (SiOₓ), an undoped silicate glass (USG), a boron-containing silicate glass (BSG), and/or a fluorine-containing silicate glass (FSG), among other examples.

As indicated above, FIG. 11 is provided as an example. Other examples may differ from what is described with regard to FIG. 11.

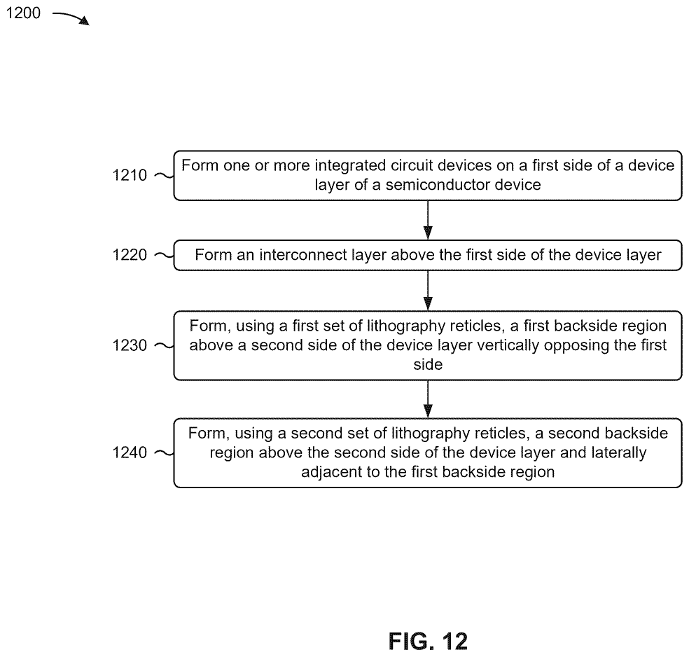

FIG. 12 is a flowchart of an example process 1200 associated with forming a semiconductor device described herein. In some implementations, one or more process blocks of FIG. 12 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 12, process 1200 may include forming one or more integrated circuit devices on a first side of a device layer of a semiconductor device (block 1210). For example, one or more semiconductor processing tools may be used to form one or more integrated circuit devices (e.g., integrated circuit devices 230) on a first side of a device layer (e.g., a device layer 222) of a semiconductor device (e.g., a semiconductor device 202), as described herein.

As further shown in FIG. 12, process 1200 may include forming an interconnect layer above the first side of the device layer (block 1220). For example, one or more semiconductor processing tools may be used to form an interconnect layer (e.g., a frontside interconnect layer 224) above the first side of the device layer, as described herein. In some implementations, the interconnect layer comprises one or more dielectric layers (e.g., dielectric layer(s) 234) and one or more conductive structures (e.g., conductive structure(s) 236) in the one or more dielectric layers. In some implementations, at least one of the integrated circuit devices is coupled to at least one of the one or more conductive structures.

As further shown in FIG. 12, process 1200 may include forming, using a first set of lithography reticles, a first backside region above a second side of the device layer vertically opposing the first side (block 1230). For example, one or more semiconductor processing tools may be used to form, using a first set of lithography reticles (e.g., a first set of reticles 108), a first backside region (e.g., a lateral region 206) above a second side of the device layer vertically opposing the first side, as described herein. In some implementations, the first set of lithography reticles is used to form a first circuit layout in the first backside region.

As further shown in FIG. 12, process 1200 may include forming, using a second set of lithography reticles, a second backside region above the second side of the device layer and laterally adjacent to the first backside region (block 1240). For example, one or more semiconductor processing tools may be used to form, using a second set of lithography reticles (e.g., a second set of reticles 108), a second backside region (e.g., a lateral region 208) above the second side of the device layer and laterally adjacent to the first backside region, as described herein. In some implementations, the second set of lithography reticles is used to form a second circuit layout in the second backside region that is different than the first circuit layout.

Process 1200 may include additional implementations, such as any single implementation or any combination of implementations described below and/or in connection with one or more other processes described elsewhere herein.

In a first implementation, the first set of lithography reticles is used to pattern the first backside region of the semiconductor device and additional first backside regions of additional semiconductor devices on a semiconductor wafer (e.g., a semiconductor wafer 110), and the second set of lithography reticles is used to pattern the second backside region of the semiconductor device and additional second backside regions of the additional semiconductor devices on the semiconductor wafer.

In a second implementation, alone or in combination with the first implementation, forming the first backside region includes using a first lithography reticle of the first set of lithography reticles to perform a first exposure operation to expose the first backside region to form a first patterned layer in the first backside region, and forming the second backside region includes using a first lithography reticle of the second set of lithography reticles to perform a second exposure operation, after the first exposure operation, to expose the second backside region to form a second patterned layer in the second backside region.

In a third implementation, alone or in combination with one or more of the first and second implementations, forming the first backside region includes using a second lithography reticle of the first set of lithography reticles to perform a third exposure operation, after the second exposure operation, to expose the first backside region to form a third patterned layer in the first backside region, and forming the second backside region includes using a second lithography reticle of the second set of lithography reticles to perform a fourth exposure operation, after the third exposure operation, to expose the second backside region to form a fourth patterned layer in the second backside region.

In a fourth implementation, alone or in combination with one or more of the first through third implementations, forming the first backside region includes using the first set of lithography masks to form a through-substrate interconnect structure (e.g., a through-substrate interconnect structure 220) through the device layer from the second side of the device layer, and forming the second backside region includes using the second set of lithography masks to form a capacitor structure (e.g., a capacitor structure 702, a capacitor structure 802, a through-substrate capacitor structure 902, a capacitor structure 1002) in the second side of the device layer.

In a fifth implementation, alone or in combination with one or more of the first through fourth implementations, forming the first backside region includes using the first set of lithography masks to form a through-substrate interconnect structure (e.g., a through-substrate interconnect structure 220) through the device layer from the second side of the device layer, and using the first set of lithography masks to form a capacitor structure (e.g., a through-substrate capacitor structure 902) above the second side of the device layer in the first backside region such that the capacitor structure and the through-substrate interconnect structure are laterally adjacent in the first backside region.

In a sixth implementation, alone or in combination with one or more of the first through fifth implementations, forming the first backside region includes using the first set of lithography masks to form a through-substrate interconnect structure (e.g., a through-substrate interconnect structure 220) through the device layer from the second side of the device layer, and forming the second backside region includes using the second set of lithography masks to form a capacitor structure (e.g., a capacitor structure 702, a capacitor structure 802, a capacitor structure 1002) above the second side of the device layer in the second backside region.

In a seventh implementation, alone or in combination with one or more of the first through sixth implementations, forming the first backside region includes using the first set of lithography masks to form a through-substrate interconnect structure (e.g., a through-substrate interconnect structure 220) through the device layer from the second side of the device layer, and forming the second backside region includes using the second set of lithography masks to form a diode structure (e.g., a diode structure 1102) in the second side of the device layer in the second backside region.

In an eighth implementation, alone or in combination with one or more of the first through seventh implementations, forming the first backside region comprises providing a semiconductor wafer (e.g., a semiconductor wafer 110), on which the semiconductor device is manufactured, onto a wafer stage (e.g., a wafer stage 136) of an EUV lithography tool (e.g., a lithography system 100), loading a lithography reticle (e.g., a reticle 108) of the first set of lithography reticles into a reticle holder (e.g., a reticle stage 140) of the EUV lithography tool, using the lithography reticle of the first set of lithography reticles to perform a first exposure operation to expose the first backside region to form a first patterned layer in the first backside region, and forming the second backside region comprises removing the lithography reticle of the first set of lithography reticles from the reticle holder after the first exposure operation, loading a lithography reticle (e.g., a reticle 108) of the second set of lithography reticles into the reticle holder of the EUV lithography tool, and using a lithography reticle of the second set of lithography reticles to perform a second exposure operation to expose the second backside region to form a second patterned layer in the second backside region.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

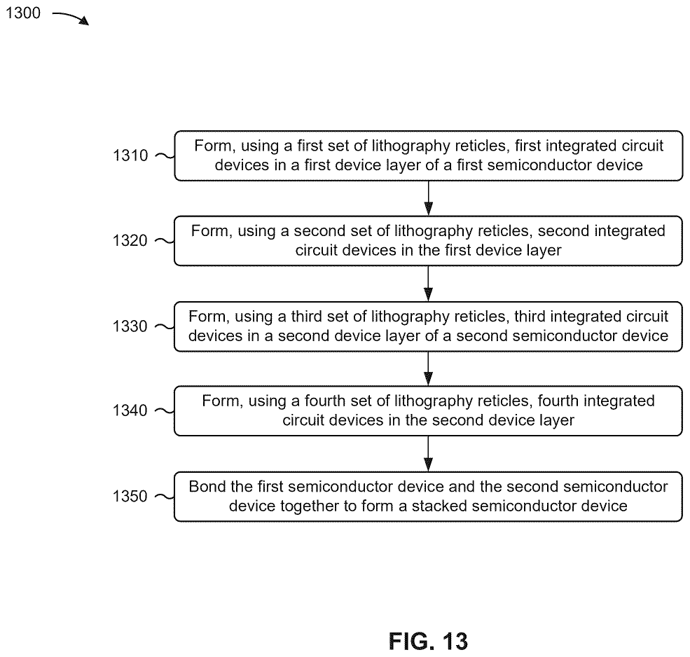

FIG. 13 is a flowchart of an example process 1300 associated with forming a semiconductor device described herein. In some implementations, one or more process blocks of FIG. 13 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 13, process 1300 may include forming, using a first set of lithography reticles, first integrated circuit devices in a first device layer of a first semiconductor device (block 1310). For example, one or more semiconductor processing tools may be used to form, using a first set of lithography reticles (e.g., a first set of reticles 108), first integrated circuit devices (e.g., first integrated circuit devices 230) in a first device layer (e.g., a device layer 222) of a first semiconductor device (e.g., a semiconductor device 202a), as described herein. In some implementations, the first set of lithography reticles is used to form a first circuit layout of the first integrated circuit devices in a first region (e.g., a lateral region 206) of the first semiconductor device.

As further shown in FIG. 13, process 1300 may include forming, using a second set of lithography reticles, second integrated circuit devices in the first device layer (block 1320). For example, one or more semiconductor processing tools may be used to form, using a second set of lithography reticles (e.g., a second set of reticles 108), second integrated circuit devices (e.g., second integrated circuit devices 230) in the first device layer, as described herein. In some implementations, the second set of lithography reticles is used to form a second circuit layout of the second integrated circuit devices in a second region (e.g., a lateral region 208) of the first semiconductor device that is laterally adjacent to the first region. In some implementations, the first circuit layout and the second circuit layout are different circuit layouts.

As further shown in FIG. 13, process 1300 may include forming, using a third set of lithography reticles, third integrated circuit devices in a second device layer of a second semiconductor device (block 1330). For example, one or more semiconductor processing tools may be used to form, using a third set of lithography reticles (e.g., a third set of reticles 108), third integrated circuit devices (e.g., third integrated circuit devices 410) in a second device layer (e.g., a device layer 404) of a second semiconductor device (e.g., a semiconductor device 202b), as described herein. In some implementations, the third set of lithography reticles is used to form a third circuit layout of the third integrated circuit devices in a third region (e.g., a lateral region 206) of the second semiconductor device.

As further shown in FIG. 13, process 1300 may include forming, using a fourth set of lithography reticles, fourth integrated circuit devices in the second device layer (block 1340). For example, one or more semiconductor processing tools may be used to form, using a fourth set of lithography reticles (e.g., a fourth set of reticles 108), fourth integrated circuit devices (e.g., fourth integrated circuit devices 410) in the second device layer, as described herein. In some implementations, the fourth set of lithography reticles is used to form a fourth circuit layout of the fourth integrated circuit devices in a fourth region (e.g., a lateral region 208) of the second semiconductor device that is laterally adjacent to the third region.

In some implementations, the third circuit layout and the fourth circuit layout are different circuit layouts.

As further shown in FIG. 13, process 1300 may include bonding the first semiconductor device and the second semiconductor device together to form a stacked semiconductor device (block 1350). For example, one or more semiconductor processing tools may be used to bond the first semiconductor device and the second semiconductor device together to form a stacked semiconductor device (e.g., a stacked semiconductor device 400, a stacked semiconductor device 614, a stacked semiconductor device 700, a stacked semiconductor device 800, a stacked semiconductor device 900, a stacked semiconductor device 1000, a stacked semiconductor device 1100), as described herein.

Process 1300 may include additional implementations, such as any single implementation or any combination of implementations described below and/or in connection with one or more other processes described elsewhere herein.

In a first implementation, process 1300 includes forming one or more first dielectric layers (e.g., first dielectric layer(s) 234) of an interconnect layer (e.g., a frontside interconnect layer 224) of the first semiconductor device above the first device layer, forming, using a fifth set of lithography reticles (e.g., a fifth set of reticles 108), first conductive structures (e.g., first conductive structures 236) in the one or more first dielectric layers, where the fifth set of lithography reticles is used to form a fifth circuit layout of the first conductive structures in the first region of the first semiconductor device, forming one or more second dielectric layers (e.g., second dielectric layer(s) 234) of the interconnect layer above the first device layer, and forming, using a sixth set of lithography reticles (e.g., a sixth set of reticles 108), second conductive structures (e.g., second conductive structures 236) in the one or more second dielectric layers, where the sixth set of lithography reticles is used to form a sixth circuit layout of the second conductive structures in the second region of the first semiconductor device, and where the fifth circuit layout and the sixth circuit layout are different circuit layouts.

In a second implementation, alone or in combination with the first implementation, process 1300 includes forming one or more third dielectric layers (e.g., third dielectric layer(s) 412) of an interconnect layer (e.g., an interconnect layer 406) of the second semiconductor device above the second device layer, forming, using a seventh set of lithography reticles (e.g., a seventh set of reticles 108), third conductive structures (e.g., third conductive structure(s) 414) in the one or more third dielectric layers, where the seventh set of lithography reticles is used to form a seventh circuit layout of the third conductive structures in the third region of the second semiconductor device, forming one or more fourth dielectric layers (e.g., fourth dielectric layer(s) 412) of the interconnect layer of the second semiconductor device above the second device layer, and forming, using an eighth set of lithography reticles (e.g., an eighth set of reticles 108), fourth conductive structures (e.g., fourth conductive structure(s) 414) in the one or more fourth dielectric layers, where the eighth set of lithography reticles is used to form an eighth circuit layout of the fourth conductive structures in the fourth region of the second semiconductor device, and where the seventh circuit layout and the eighth circuit layout are different circuit layouts.

In a third implementation, alone or in combination with one or more of the first and second implementations, process 1300 includes forming, using a fifth set of lithography reticles (e.g., a ninth set of reticles 108), a first backside region (e.g., a lateral region 206) above a backside of the first device layer, where the ninth set of lithography reticles is used to form a ninth circuit layout in the first backside region after bonding the first semiconductor device and the second semiconductor device, and forming, using a tenth set of lithography reticles (e.g., a tenth set of reticles 108), a second backside region (e.g., a lateral region 208) above the backside of the first device layer and laterally adjacent to the first backside region, where the tenth set of lithography reticles is used to form a tenth circuit layout in the second backside region after bonding the first semiconductor device and the second semiconductor device, and where the ninth circuit layout and the tenth circuit layout are different circuit layouts.

In a fourth implementation, alone or in combination with one or more of the first through third implementations, the first circuit layout and the third circuit layout are mirrored circuit layouts, and the second circuit layout and the fourth circuit layout are mirrored circuit layouts.

In a fifth implementation, alone or in combination with one or more of the first through fourth implementations, the first circuit layout and the third circuit layout are asymmetric circuit layouts, and the second circuit layout and the fourth circuit layout are asymmetric circuit layouts.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

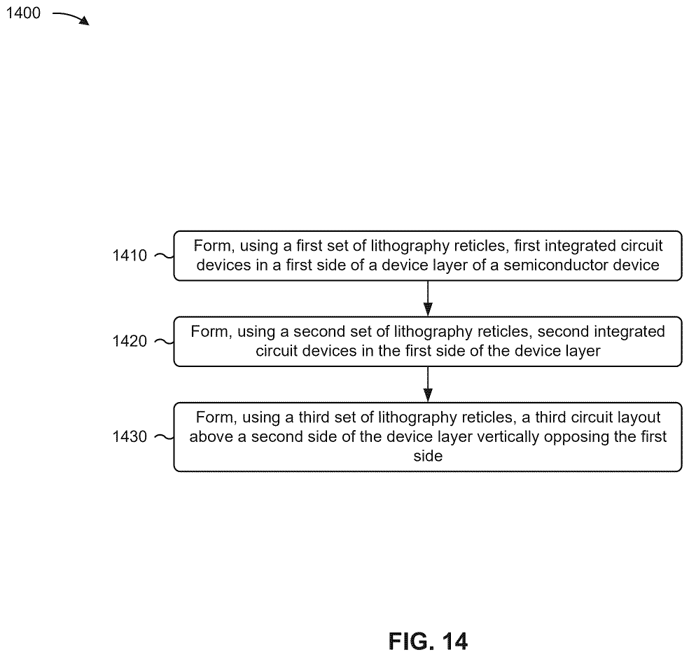

FIG. 14 is a flowchart of an example process 1400 associated with forming a semiconductor device described herein. In some implementations, one or more process blocks of FIG. 14 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 14, process 1400 may include forming, using a first set of lithography reticles, first integrated circuit devices in a first side of a device layer of a semiconductor device (block 1410). For example, one or more semiconductor processing tools may be used to form, using a first set of lithography reticles (e.g., a first set of reticles 108), first integrated circuit devices (e.g., first integrated circuit devices 230) in a first side of a device layer (e.g., a device layer 222) of a semiconductor device (e.g., a semiconductor device 202a), as described herein. In some implementations, the first set of lithography reticles is used to form a first circuit layout of the first integrated circuit devices in a first region (e.g., a lateral region 206) of the semiconductor device.

As further shown in FIG. 14, process 1400 may include forming, using a second set of lithography reticles, second integrated circuit devices in the first side of the device layer (block 1420). For example, one or more semiconductor processing tools may be used to form, using a second set of lithography reticles (e.g., a second set of reticles 108), second integrated circuit devices (e.g., second integrated circuit devices 230) in the first side of the device layer, as described herein. In some implementations, the second set of lithography reticles is used to form a second circuit layout of the second integrated circuit devices in a second region (e.g., a lateral region 208) of the semiconductor device that is laterally adjacent to the first region. In some implementations, the first circuit layout and the second circuit layout are different circuit layouts.

As further shown in FIG. 14, process 1400 may include forming, using a third set of lithography reticles, a third circuit layout above a second side of the device layer vertically opposing the first side (block 1430). For example, one or more semiconductor processing tools may be used to form, using a third set of lithography reticles (e.g., a third set of reticles 108), a third circuit layout above a second side of the device layer vertically opposing the first side, as described herein. In some implementations, the third set of lithography reticles is used to form a third circuit layout in the first region.

Process 1400 may include additional implementations, such as any single implementation or any combination of implementations described below and/or in connection with one or more other processes described elsewhere herein.

In a first implementation, forming the third circuit layout comprises forming a through-substrate interconnect structure (e.g., a through-substrate interconnect structure 220) and a capacitor structure (e.g., a through-substrate capacitor structure 902) in the first region.

In a second implementation, alone or in combination with the first implementation, process 1400 includes bonding the semiconductor device to a carrier substrate (e.g., a carrier substrate 302) after forming the first integrated circuit devices and the second integrated circuit devices, where forming the third circuit layout above the second side of the device layer includes forming the third circuit layout above the second side of the device layer after bonding the semiconductor device to the carrier substrate.

In a third implementation, alone or in combination with one or more of the first and second implementations, process 1400 includes forming one or more first dielectric layers (e.g., first dielectric layer(s) 234) of an interconnect layer (e.g., a frontside interconnect layer 224) of the semiconductor device above the first side of the device layer, forming, using a fourth set of lithography reticles (e.g., a fourth set of reticles 108), first conductive structures (e.g., first conductive structure(s) 236) in the one or more first dielectric layers, where the fourth set of lithography reticles is used to form a fourth circuit layout of the first conductive structures in the first region of the semiconductor device, forming one or more second dielectric layers (e.g., second dielectric layer(s) 234) of the interconnect layer above the first side of the device layer, and forming, using a fifth set of lithography reticles (e.g., a fifth set of reticles 108), second conductive structures (e.g., second conductive structure(s) 236) in the one or more second dielectric layers, where the fifth set of lithography reticles is used to form a fifth circuit layout of the second conductive structures in the second region of the semiconductor device, and where the fourth circuit layout and the fifth circuit layout are different circuit layouts.

In a fourth implementation, alone or in combination with one or more of the first through third implementations, forming the third circuit layout above the second side of the device layer includes forming the third circuit layout above the second side of the device layer after forming the interconnect layer.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, a multiple-reticle exposure technique is used to manufacture different lateral regions of a semiconductor device (e.g., a monolithic superchip). The multiple-reticle exposure technique may be used for frontside processing and for backside processing of a semiconductor device. For example, different sets of reticles may be used to pattern different lateral regions on the frontside of the semiconductor device, and different sets of reticles may be used to pattern different lateral regions on the backside of the semiconductor device. This further expands the capability of implementing diverse sets of functional areas across the semiconductor device to the backside as well as the frontside for the semiconductor device.

Moreover, the use of the multiple-reticle exposure technique on the backside of the semiconductor device is compatible with direct bonding of the semiconductor device to another semiconductor device to form 3DIC devices.

As described in greater detail above, some implementations described herein provide a method. The method includes forming one or more integrated circuit devices on a first side of a device layer of a semiconductor device. The method includes forming an interconnect layer above the first side of the device layer, where the interconnect layer comprises one or more dielectric layers and one or more conductive structures in the one or more dielectric layers, and where at least one of the integrated circuit devices is coupled to at least one of the one or more conductive structures. The method includes forming, using a first set of lithography reticles, a first backside region above a second side of the device layer vertically opposing the first side, where the first set of lithography reticles is used to form a first circuit layout in the first backside region. The method includes forming, using a second set of lithography reticles, a second backside region above the second side of the device layer and laterally adjacent to the first backside region, where the second set of lithography reticles is used to form a second circuit layout in the second backside region that is different than the first circuit layout.

As described in greater detail above, some implementations described herein provide a method. The method includes forming, using a first set of lithography reticles, first integrated circuit devices in a first device layer of a first semiconductor device, where the first set of lithography reticles is used to form a first circuit layout of the first integrated circuit devices in a first region of the first semiconductor device. The method includes forming, using a second set of lithography reticles, second integrated circuit devices in the first device layer, where the second set of lithography reticles is used to form a second circuit layout of the second integrated circuit devices in a second region of the first semiconductor device that is laterally adjacent to the first region, and where the first circuit layout and the second circuit layout are different circuit layouts. The method includes forming, using a third set of lithography reticles, third integrated circuit devices in a second device layer of a second semiconductor device, where the third set of lithography reticles is used to form a third circuit layout of the third integrated circuit devices in a third region of the second semiconductor device. The method includes forming, using a fourth set of lithography reticles, fourth integrated circuit devices in the second device layer, where the fourth set of lithography reticles is used to form a fourth circuit layout of the fourth integrated circuit devices in a fourth region of the second semiconductor device that is laterally adjacent to the third region, and where the third circuit layout and the fourth circuit layout are different circuit layouts.

The method includes bonding the first semiconductor device and the second semiconductor device together to form a stacked semiconductor device.

As described in greater detail above, some implementations described herein provide a method. The method includes forming, using a first set of lithography reticles, first integrated circuit devices in a first side of a device layer of a semiconductor device, where the first set of lithography reticles is used to form a first circuit layout of the first integrated circuit devices in a first region of the semiconductor device. The method includes forming, using a second set of lithography reticles, second integrated circuit devices in the first side of the device layer, where the second set of lithography reticles is used to form a second circuit layout of the second integrated circuit devices in a second region of the semiconductor device that is laterally adjacent to the first region, and where the first circuit layout and the second circuit layout are different circuit layouts. The method includes forming, using a third set of lithography reticles, a third circuit layout above a second side of the device layer vertically opposing the first side, where the third set of lithography reticles is used to form a third circuit layout in the first region.

The terms “approximately” and “substantially” can indicate a value of a given quantity that varies within 5% of the value (e.g., ±1%, +2%, +3%, +4%, +5% of the value).

These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming one or more integrated circuit devices on a first side of a device layer of a semiconductor device;
forming an interconnect layer above the first side of the device layer,
wherein the interconnect layer comprises one or more dielectric layers and one or more conductive structures in the one or more dielectric layers, and
wherein at least one of the integrated circuit devices is coupled to at least one of the one or more conductive structures;
forming, using a first set of lithography reticles, a first backside region above a second side of the device layer vertically opposing the first side,
wherein the first set of lithography reticles is used to form a first circuit layout in the first backside region; and
forming, using a second set of lithography reticles, a second backside region above the second side of the device layer and laterally adjacent to the first backside region,
wherein the second set of lithography reticles is used to form a second circuit layout in the second backside region that is different than the first circuit layout.

2. The method of claim 1, wherein the first set of lithography reticles is used to pattern the first backside region of the semiconductor device and additional first backside regions of additional semiconductor devices on a semiconductor wafer; and
wherein the second set of lithography reticles is used to pattern the second backside region of the semiconductor device and additional second backside regions of the additional semiconductor devices on the semiconductor wafer.

3. The method of claim 1, wherein forming the first backside region comprises:
using a first lithography reticle of the first set of lithography reticles to perform a first exposure operation to expose the first backside region to form a first patterned layer in the first backside region; and
wherein forming the second backside region comprises:
using a first lithography reticle of the second set of lithography reticles to perform a second exposure operation, after the first exposure operation, to expose the second backside region to form a second patterned layer in the second backside region.

4. The method of claim 3, wherein forming the first backside region comprises:
using a second lithography reticle of the first set of lithography reticles to perform a third exposure operation, after the second exposure operation, to expose the first backside region to form a third patterned layer in the first backside region; and
wherein forming the second backside region comprises:
using a second lithography reticle of the second set of lithography reticles to perform a fourth exposure operation, after the third exposure operation, to expose the second backside region to form a fourth patterned layer in the second backside region.

5. The method of claim 1, wherein forming the first backside region comprises:
using the first set of lithography masks to form a through-substrate interconnect structure through the device layer from the second side of the device layer; and
wherein forming the second backside region comprises:
using the second set of lithography masks to form a capacitor structure in the second side of the device layer.

6. The method of claim 1, wherein forming the first backside region comprises:
using the first set of lithography masks to form a through-substrate interconnect structure through the device layer from the second side of the device layer; and
using the first set of lithography masks to form a capacitor structure above the second side of the device layer in the first backside region such that the capacitor structure and the through-substrate interconnect structure are laterally adjacent in the first backside region.

7. The method of claim 1, wherein forming the first backside region comprises:
using the first set of lithography masks to form a through-substrate interconnect structure through the device layer from the second side of the device layer; and
wherein forming the second backside region comprises:
using the second set of lithography masks to form a capacitor structure above the second side of the device layer in the second backside region.

8. The method of claim 1, wherein forming the first backside region comprises:
using the first set of lithography masks to form a through-substrate interconnect structure through the device layer from the second side of the device layer; and
wherein forming the second backside region comprises:
using the second set of lithography masks to form a diode structure in the second side of the device layer in the second backside region.

9. The method of claim 1, wherein forming the first backside region comprises:
providing a semiconductor wafer, on which the semiconductor device is manufactured, onto a wafer stage of an extreme ultraviolet (EUV) lithography tool;
loading a lithography reticle of the first set of lithography reticles into a reticle holder of the EUV lithography tool;
using the lithography reticle of the first set of lithography reticles to perform a first exposure operation to expose the first backside region to form a first patterned layer in the first backside region;
wherein forming the second backside region comprises:
removing the lithography reticle of the first set of lithography reticles from the reticle holder after the first exposure operation;
loading a lithography reticle of the second set of lithography reticles into the reticle holder of the EUV lithography tool; and
using a lithography reticle of the second set of lithography reticles to perform a second exposure operation to expose the second backside region to form a second patterned layer in the second backside region.

10. A method, comprising:
forming, using a first set of lithography reticles, first integrated circuit devices in a first device layer of a first semiconductor device,
wherein the first set of lithography reticles is used to form a first circuit layout of the first integrated circuit devices in a first region of the first semiconductor device;
forming, using a second set of lithography reticles, second integrated circuit devices in the first device layer,
wherein the second set of lithography reticles is used to form a second circuit layout of the second integrated circuit devices in a second region of the first semiconductor device that is laterally adjacent to the first region, and
wherein the first circuit layout and the second circuit layout are different circuit layouts;
forming, using a third set of lithography reticles, third integrated circuit devices in a second device layer of a second semiconductor device,
wherein the third set of lithography reticles is used to form a third circuit layout of the third integrated circuit devices in a third region of the second semiconductor device;
forming, using a fourth set of lithography reticles, fourth integrated circuit devices in the second device layer,
wherein the fourth set of lithography reticles is used to form a fourth circuit layout of the fourth integrated circuit devices in a fourth region of the second semiconductor device that is laterally adjacent to the third region, and
wherein the third circuit layout and the fourth circuit layout are different circuit layouts; and
bonding the first semiconductor device and the second semiconductor device together to form a stacked semiconductor device.

11. The method of claim 10, further comprising:
forming one or more first dielectric layers of an interconnect layer of the first semiconductor device above the first device layer;
forming, using a fifth set of lithography reticles, first conductive structures in the one or more first dielectric layers,
wherein the fifth set of lithography reticles is used to form a fifth circuit layout of the first conductive structures in the first region of the first semiconductor device;
forming one or more second dielectric layers of the interconnect layer above the first device layer; and
forming, using a sixth set of lithography reticles, second conductive structures in the one or more second dielectric layers,
wherein the sixth set of lithography reticles is used to form a sixth circuit layout of the second conductive structures in the second region of the first semiconductor device, and
wherein the fifth circuit layout and the sixth circuit layout are different circuit layouts.

12. The method of claim 11, further comprising:
forming one or more third dielectric layers of an interconnect layer of the second semiconductor device above the second device layer;
forming, using a seventh set of lithography reticles, third conductive structures in the one or more third dielectric layers,
wherein the seventh set of lithography reticles is used to form a seventh circuit layout of the third conductive structures in the third region of the second semiconductor device;
forming one or more fourth dielectric layers of the interconnect layer of the second semiconductor device above the second device layer; and
forming, using an eighth set of lithography reticles, fourth conductive structures in the one or more fourth dielectric layers,
wherein the eighth set of lithography reticles is used to form an eighth circuit layout of the fourth conductive structures in the fourth region of the second semiconductor device, and
wherein the seventh circuit layout and the eighth circuit layout are different circuit layouts.

13. The method of claim 11, further comprising:
forming, using a ninth set of lithography reticles, a first backside region above a backside of the first device layer,
wherein the ninth set of lithography reticles is used to form a ninth circuit layout in the first backside region after bonding the first semiconductor device and the second semiconductor device; and
forming, using a tenth set of lithography reticles, a second backside region above the backside of the first device layer and laterally adjacent to the first backside region,
wherein the tenth set of lithography reticles is used to form a sixth-tenth circuit layout in the second backside region after bonding the first semiconductor device and the second semiconductor device, and
wherein the ninth circuit layout and the tenth circuit layout are different circuit layouts.

14. The method of claim 10, wherein the first circuit layout and the third circuit layout are mirrored circuit layouts; and
wherein the second circuit layout and the fourth circuit layout are mirrored circuit layouts.

15. The method of claim 10, wherein the first circuit layout and the third circuit layout are asymmetric circuit layouts; and
wherein the second circuit layout and the fourth circuit layout are asymmetric circuit layouts.

16. A method, comprising:
forming, using a first set of lithography reticles, first integrated circuit devices in a first side of a device layer of a semiconductor device,
wherein the first set of lithography reticles is used to form a first circuit layout of the first integrated circuit devices in a first region of the semiconductor device;
forming, using a second set of lithography reticles, second integrated circuit devices in the first side of the device layer,
wherein the second set of lithography reticles is used to form a second circuit layout of the second integrated circuit devices in a second region of the semiconductor device that is laterally adjacent to the first region, and
wherein the first circuit layout and the second circuit layout are different circuit layouts; and
forming, using a third set of lithography reticles, a third circuit layout above a second side of the device layer vertically opposing the first side,
wherein the third set of lithography reticles is used to form a third circuit layout in the first region.

17. The method of claim 16, wherein forming the third circuit layout comprises:
forming a through-substrate interconnect structure and a capacitor structure in the first region.

18. The method of claim 16, further comprising:
bonding the semiconductor device to a carrier substrate after forming the first integrated circuit devices and the second integrated circuit devices,
wherein forming the third circuit layout above the second side of the device layer comprises:
forming the third circuit layout above the second side of the device layer after bonding the semiconductor device to the carrier substrate.

19. The method of claim 16, further comprising:
forming one or more first dielectric layers of an interconnect layer of the semiconductor device above the first side of the device layer;
forming, using a fourth set of lithography reticles, first conductive structures in the one or more first dielectric layers,
wherein the fourth set of lithography reticles is used to form a fourth circuit layout of the first conductive structures in the first region of the semiconductor device;
forming one or more second dielectric layers of the interconnect layer above the first side of the device layer; and
forming, using a fifth set of lithography reticles, second conductive structures in the one or more second dielectric layers,
wherein the fifth set of lithography reticles is used to form a fifth circuit layout of the second conductive structures in the second region of the semiconductor device, and
wherein the fourth circuit layout and the fifth circuit layout are different circuit layouts.

20. The method of claim 19, wherein forming the third circuit layout above the second side of the device layer comprises:
forming the third circuit layout above the second side of the device layer after forming the interconnect layer.
